(19) United States
(12) Patent Application Publication
(10) Pub. No.: US 2026/0107651 A1
(43) Pub. Date: Apr. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Seungjun Lee, Yongin-si (KR); Junggun Nam, Yongin-si (KR)

(21) Appl. No.: 19/348,273

(22) Filed: Oct. 2, 2025

(30) Foreign Application Priority Data
Oct. 11, 2024 (KR) 10-2024-0138428

(51) Int. Cl. H10K 59/131; H10H 29/30; H10H 29/34; H10H 29/49; H10K 59/35; H10K 102/00

(52) U.S. Cl. CPC H10K 59/131; H10H 29/345; H10H 29/352; H10H 29/49; H10K 59/352; H10K 59/353; H10K 2102/311

(57) ABSTRACT

Provided is a display device configured to be stretched, the display device including a display panel having a non-display area, and a display area inside the non-display area in plan view, and having pixel groups repeatedly arranged in a first direction and a second direction and including pixels in a first sub-pixel group and a second sub-pixel group, the pixels being configured to emit light or not to emit light when the display device is in a stretched state such that a number of light-emitting pixels of the pixels increases as a degree of stretching of the display device increases, and ones of the pixels in the first sub-pixel group or in the second sub-pixel group being configured to emit light when the display device is in a non-stretched state.

### CROSS-REFERENCE TO RELATED APPLICATION

The present application claims priority to, and the benefit of, Korean Patent Application No. 10-2024-0138428, filed on Oct. 11, 2024, in the Korean Intellectual Property Office, the entire disclosure of which is incorporated herein by reference.

### BACKGROUND

### 1. Field

One or more embodiments relate to a stretchable display device.

### 2. Description of the Related Art

As display devices that visually display electrical signals have been developed, various display devices having excellent characteristics, such as thinness, light weight, and low power consumption, have been introduced. For example, flexible display devices that are foldable or rollable have been introduced. Recently, research and development have been actively conducted on stretchable display devices that may be changed into various shapes.

### SUMMARY

One or more embodiments include a display device having improved display quality. However, the embodiments are only examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display device is configured to be stretched, the display device comprising pixels in pixel groups repeatedly arranged in a first direction and a second direction in a display area. Each of the pixel groups comprises a first sub-pixel group and a second sub-pixel group. The pixels in the first sub-pixel group and the second sub-pixel group in each of the pixel groups are configured to emit light or not to emit light when the display device is in a stretched state such that a number of light-emitting pixels of the pixels increases as a degree of stretching of the display device increases, and ones of the pixels in the first sub-pixel group or in the second sub-pixel group in each of the pixel groups are configured to emit light when the display device is in a non-stretched state.

Locations of the light-emitting pixels may be repeated in units of pixel groups when the display device is in the stretched state.

Upper, lower, left, right, and/or diagonal ones of the pixels may be configured to symmetrically emit light or to symmetrically not emit light, with respect to a central one of the pixels, at each stretching stage corresponding to the degree of the stretching.

Non-light-emitting pixels of the pixels may be not adjacent in the first direction or the second direction when the display device is in the stretched state.

The display area may include island portions and bridge portions connecting the island portions, and wherein the pixels are in the island portions and include sub-pixels. And the display panel further comprises conductive lines connected to the pixels in the bridge portions.

The island portions may include first island portions and second island portions that are alternately arranged and separated in the first direction and the second direction.

The bridge portions may include first bridge portions connecting island portions arranged in the first direction, and second bridge portions connecting island portions arranged in the second direction.

The display device may further include a first common voltage line and a second common voltage line in the first bridge portions, the first common voltage line being connected to ones of the pixels in the first island portions arranged in the first direction, and the second common voltage line being connected to others of the pixels in the second island portions arranged in the first direction, and a first driving voltage line and a second driving voltage line in the second bridge portions, the first driving voltage line being connected to ones of the pixels in the first island portions arranged in the second direction, and the second driving voltage line being connected to others of the pixels in the second island portions arranged in the second direction.

The first common voltage line and the second common voltage line may be at different respective layers, wherein the first driving voltage line and the second driving voltage line are at different respective layers.

The display device may further include a first gate line and a second gate line in the first bridge portions, the first gate line being connected to ones of the pixels in the first island portions arranged in the first direction, and the second gate line being connected to others of the pixels in the second island portions arranged in the first direction, and a data line in the second bridge portions and connected to ones of the pixels in the first island portions and in the second island portions arranged in the second direction.

The display device may further include a common voltage supply line in a non-display area outside the display area and connected to the first common voltage line and the second common voltage line, and a driving voltage supply line in the non-display area and connected to the first driving voltage line and the second driving voltage line.

According to one or more embodiments, a display device is configured to be stretched, and has a display area, and a non-display area outside the display area, the display device including conductive lines, and pixel groups connected to the conductive lines and arranged in a first direction and in a second direction in the display area. Each of the pixel groups includes pixels in a first sub-pixel group and in a second sub-pixel group, The pixels in the first sub-pixel group and in the second sub-pixel group in each of the pixel groups are configured to emit light or not to emit light such that a number of light-emitting pixels of the pixels increases as a degree of stretching of the display device increases, and ones of the pixels in the first sub-pixel group or in the second sub-pixel group in each of the pixel groups are configured to emit light when the display device is in a non-stretched state.

The display area may include first island portions and second island portions with the pixels therein, and alternately arranged to be separated in the first direction and the second direction in the display area, and bridge portions with the conductive lines therein, and connecting the first island portions and the second island portions.

The conductive lines may include a common voltage line including a first common voltage line connected to ones of the pixels in the first island portions arranged in the first direction, and a second common voltage line connected to others of the pixels in the second island portions arranged in the first direction, and a driving voltage line includes a first driving voltage line connected to ones of the pixels in the first island portions arranged in the second direction, and a second driving voltage line connected to others of the pixels in the second island portions arranged in the second direction.

The first common voltage line and the second common voltage line may be at different respective layers, wherein the first driving voltage line and the second driving voltage line are at different respective layers.

Upper, lower, left, right, and/or diagonal ones of the pixels may be configured to symmetrically emit light or to symmetrically not emit light with respect to a central pixel corresponding to the degree of the stretching.

Non-light-emitting pixels of the pixels may be not adjacent in the first direction or the second direction when the display device is in the stretched state.

According to one or more embodiments, an electronic device includes a display device comprising pixels in pixel groups repeatedly arranged in a first direction and a second direction in a display area, each of the pixel groups including a first sub-pixel group and a second sub-pixel group, and including pixels, a sensing unit configured to sense stretching of the display device, and a processor configured to receive, from the sensing unit, a sensing signal corresponding to the stretching, determine a degree of the stretching based on the sensing signal, output an image signal corresponding to the degree of the stretching, control ones of the pixels of the first sub-pixel group or of the second sub-pixel group to emit light when the display device is in a non-stretched state, and control the pixels of the first sub-pixel group and of the second sub-pixel group to emit light or not to emit light when the display device is in a stretched state such that a number of light-emitting pixels of the pixels increases as the degree of the stretching increases.

Upper, lower, left, right, and/or diagonal ones of the pixels may be configured to symmetrically emit light or to symmetrically not emit light with respect to a central pixel corresponding to the degree of the stretching.

Non-light-emitting pixels of the pixels may be not adjacent in the first direction or the second direction when the display device is in the stretched state.

### BRIEF DESCRIPTION OF THE DRAWINGS

The above and other aspects of certain embodiments of the disclosure will be more apparent from the following description taken in conjunction with the accompanying drawings, in which:

FIG. 1 is a perspective view schematically illustrating a display device according to one or more embodiments;

FIGS. 2A and 2B are perspective views illustrating a state in which the display device of FIG. 1 is stretched in a first direction;

FIG. 2C is a perspective view illustrating a state in which the display device of FIG. 1 is stretched in a second direction;

FIG. 2D is a perspective view illustrating a state in which the display device of FIG. 1 is stretched in first and second directions;

FIG. 2E is a perspective view illustrating a state in which the display device of FIG. 1 is stretched in a third direction;

FIG. 3 is a plan view schematically illustrating a display device according to one or more embodiments;

FIG. 4 is an enlarged plan view of region A of FIG. 3 as a portion of a display device according to one or more embodiments;

FIG. 5 is a cross-sectional view schematically illustrating a first island portion and a first bridge portion that are arranged in a display area of a display device, according to one or more embodiments;

FIG. 6A is a cross-sectional view schematically illustrating a light-emitting element of a display device according to one or more embodiments;

FIG. 6B is a cross-sectional view schematically illustrating a light-emitting element of a display device according to one or more embodiments;

FIGS. 7A and 7B are diagrams schematically illustrating a portion of a display area according to one or more embodiments;

FIGS. 8A to 8L are diagrams illustrating a light emission state of a pixel constituting a pixel group, according to one or more embodiments;

FIG. 9 is a diagram schematically illustrating a pixel group according to one or more embodiments;

FIGS. 10A to 10D are diagrams schematically illustrating a light emission state of a pixel group at each stretching stage corresponding to a degree of stretching;

FIG. 11 is a diagram schematically illustrating a pixel group according to one or more embodiments;

FIGS. 12A to 12D are diagrams schematically illustrating a light emission state of a pixel group according to a degree of stretching;

FIG. 13 is a diagram schematically illustrating a pixel group according to one or more embodiments;

FIGS. 14A to 14D are diagrams schematically illustrating a light emission state of a pixel group according to a degree of stretching;

FIGS. 15A and 15B are diagrams schematically illustrating conductive lines in a display area according to one or more embodiments;

FIG. 16 is a diagram schematically illustrating cross-sections of a first island portion, a first bridge portion in a first direction, and a first bridge portion in a second direction, according to one or more embodiments;

FIG. 17 is a diagram schematically illustrating an electronic device including a display device, according to one or more embodiments;

FIG. 18 is a diagram schematically explaining driving of a display device according to one or more embodiments; and

FIGS. 19A to 19G are perspective views schematically illustrating embodiments of electronic devices each including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B.

Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure. ” Furthermore, the expression “being the same” may mean “being substantially the same”. In other words, the expression “being the same” may include a range that can be tolerated by those of ordinary skill in the art. The other expressions may also be expressions from which “substantially”has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

It will be understood that each block of flowchart illustrations and combinations of blocks in the flowchart illustrations according to the embodiments may be performed by computer program instructions. Because these computer program instructions may be loaded into a processor of a general-purpose computer, special-purpose computer, or other programmable data processing device, the instructions, which are executed via the processor of the computer or other programmable data processing device, generate means for performing functions specified in the flowchart block(s). Because these computer program instructions may also be stored in a computer-usable or computer-readable memory that may direct a computer or other programmable data processing device to function in a particular manner, the instructions stored in the computer-usable or computer-readable memory may produce an article of manufacture including instruction means for performing the functions specified in the flowchart block(s). Because the computer program instructions may also be loaded onto a computer or other programmable data processing device, a series of operational steps may be performed on the computer or other programmable device to produce a computer implemented process, and thus, the instructions executed on the computer or other programmable device may provide steps for performing the functions specified in the flowchart block(s).

In addition, each block of the flowchart illustrations may represent a module, segment, or portion of code, which includes one or more executable instructions for performing specified logical function(s). It should also be noted that in some alternative implementations, the functions noted in the blocks may occur out of the order. For example, two blocks shown in succession may in fact be performed substantially simultaneously, or the blocks may sometimes be performed in the reverse order depending on the corresponding function.

Here, the term “unit” in the embodiments refers to a software component or hardware component, such as a field-programmable gate array (FPGA) or an application-specific integrated circuit (ASIC), and performs certain functions. However, the term “unit” is not limited to software or hardware. A “unit” may be configured in an addressable storage medium, or may be configured to reproduce one or more processors. Thus, for example, a “unit” may refer to components such as software components, object-oriented software components, class components, and task components, and may include processes, functions, attributes, procedures, subroutines, segments of program code, drivers, firmware, micro codes, circuits, data, a database, data structures, tables, arrays, and variables. The functionality provided in components and “units” may be combined into fewer components and “units,” or may be further separated into additional components and “units.” Further, the components and “units” or may be implemented to operate one or more central processing units (CPUs) in a device or a secure multimedia card.

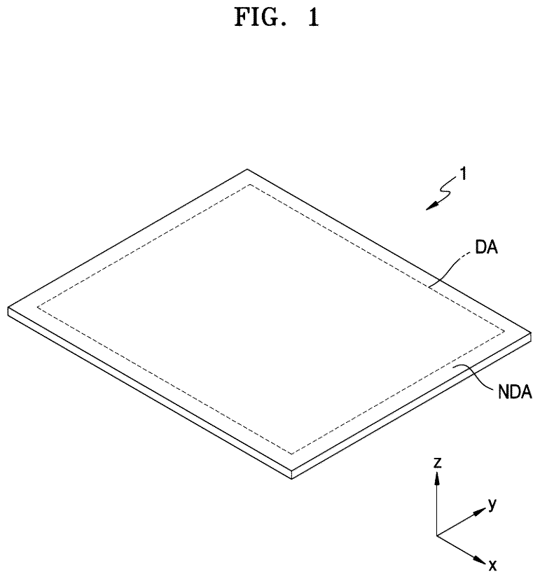

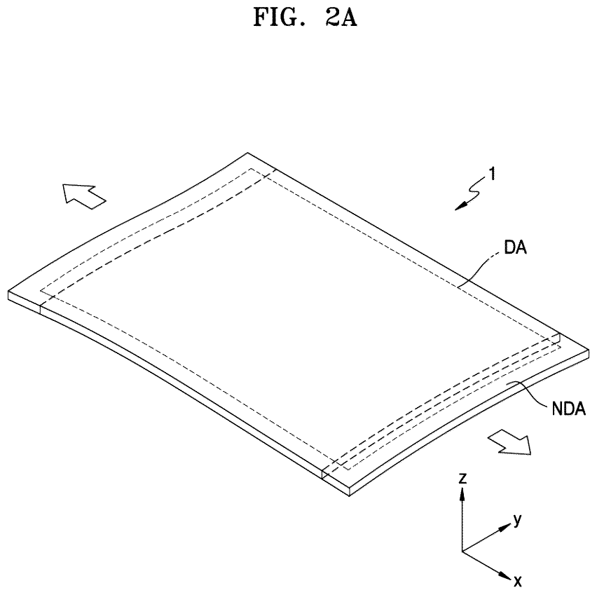

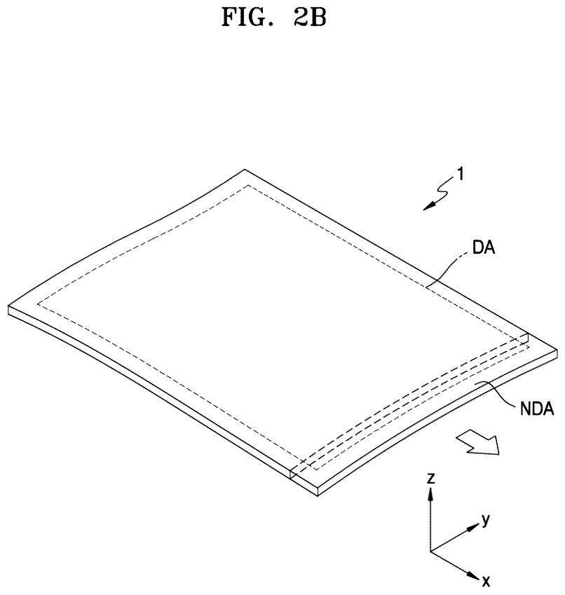

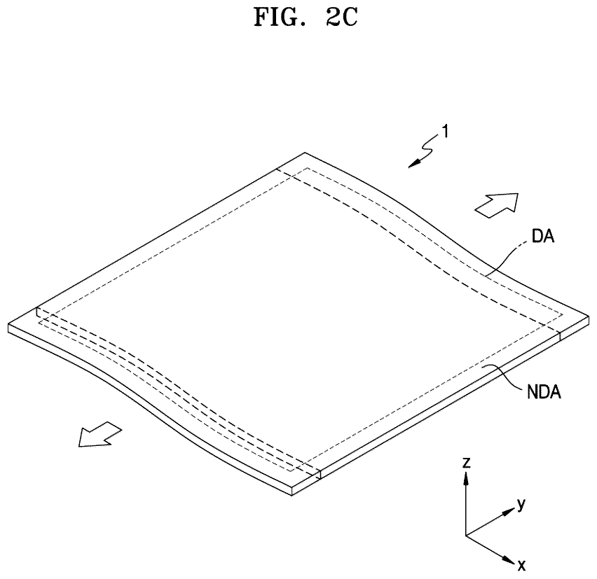

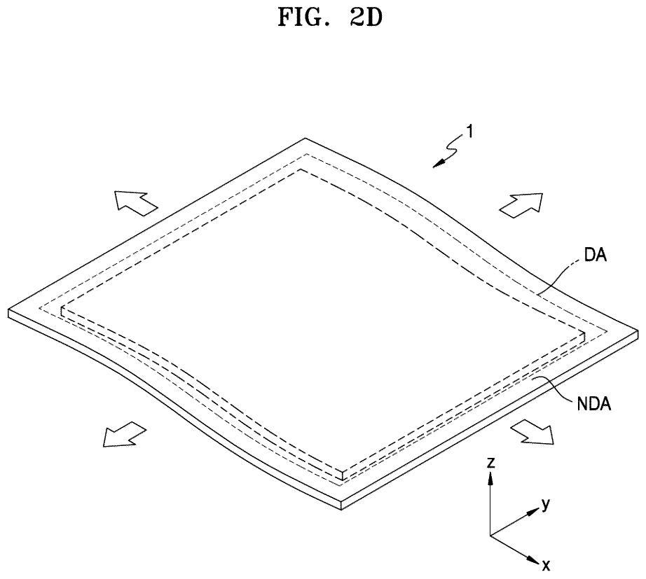

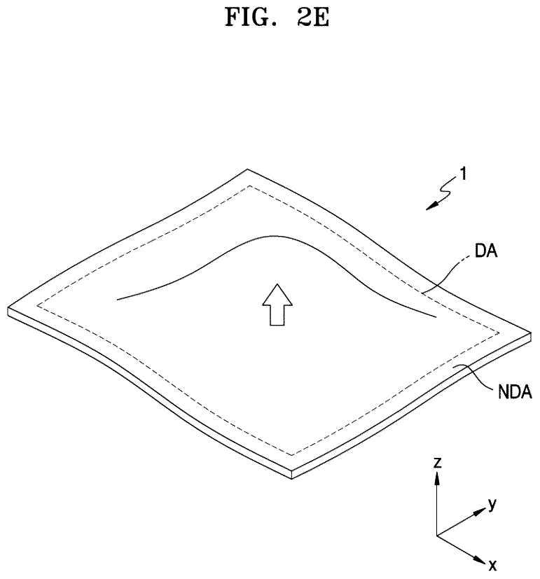

FIG. 1 is a perspective view schematically illustrating a display device 1 according to one or more embodiments. FIGS. 2A and 2B are perspective views illustrating a state in which the display device 1 of FIG. 1 is stretched in a first direction. FIG. 2C is a perspective view illustrating a state in which the display device 1 of FIG. 1 is stretched in a second direction. FIG. 2D is a perspective view illustrating a state in which the display device 1 of FIG. 1 is stretched in the first and second directions. FIG. 2E is a perspective view illustrating a state in which the display device 1 of FIG. 1 is stretched in a third direction.

Referring to FIG. 1, the display device 1 may be a stretchable and recoverable display device that may be stretched, or may be recovered to its original state, in various directions. The display device 1 may include a display area DA and a non-display area NDA. The display area DA may include a plurality of pixels. The display device 1 may provide a corresponding image by using light emitted from the plurality of pixels. The non-display area NDA may be arranged outside the display area DA. The non-display area NDA may entirely surround the display area DA.

The display device 1 may be stretched in a first direction (e.g., an x-direction and/or a −x-direction) due to an external force applied by an external object or a user. In one or more embodiments, as shown in FIGS. 2A and 2B, the display area DA and/or the non-display area NDA of the display device 1 may be stretched in the first direction (e.g., the x-direction and/or the −x-direction). For example, the display device 1 may be stretched in the x-direction and the −x-direction, as shown in FIG. 2A, or may be stretched in the x-direction or the −x-direction while one side of the display device 1 is fixed. FIG. 2B shows an example in which the display device 1 is stretched in the x-direction while one side of the display device 1 is fixed.

The display device 1 may be stretched in a second direction (e.g., a y-direction and/or a −y-direction) due to an external force applied by an external object or a user. In one or more embodiments, as shown in FIG. 2C, the display area DA and/or the non-display area NDA of the display device 1 may be stretched in the y-direction and the −y-direction. In one or more other embodiments, the display device 1 may be stretched in the y-direction or the −y-direction while one side of the display device 1 is fixed.

The display device 1 may be stretched in a plurality of directions, for example, in the first direction (e.g., the x-direction and/or the −x-direction) and the second direction (e.g., the y-direction and/or the −y-direction), due to an external force applied by an external object or a part of the human body. As shown in FIG. 2D, the display area DA and/or the non-display area NDA of the display device 1 may be stretched in the ±x-direction and the ±y-direction.

The display device 1 may be stretched in a third direction (e.g., a z-direction or a −z-direction) due to an external force applied by an external object or a part of the human body. In one or more embodiments, FIG. 2E shows that a portion of the display device 1, for example, a portion of the display area DA, protrudes in the z-direction. In one or more other embodiments, a portion of the display device 1, for example, a portion of the display area DA, may protrude in the −z-direction (or be recessed in the z-direction).

FIGS. 2A to 2E show that the display device 1 is stretched in the first direction, the second direction, and/or the third direction, but the disclosure is not limited thereto. In one or more other embodiments, the display device 1 may be variously deformed into an irregular shape, for example, may be bent or twisted along two or more axes.

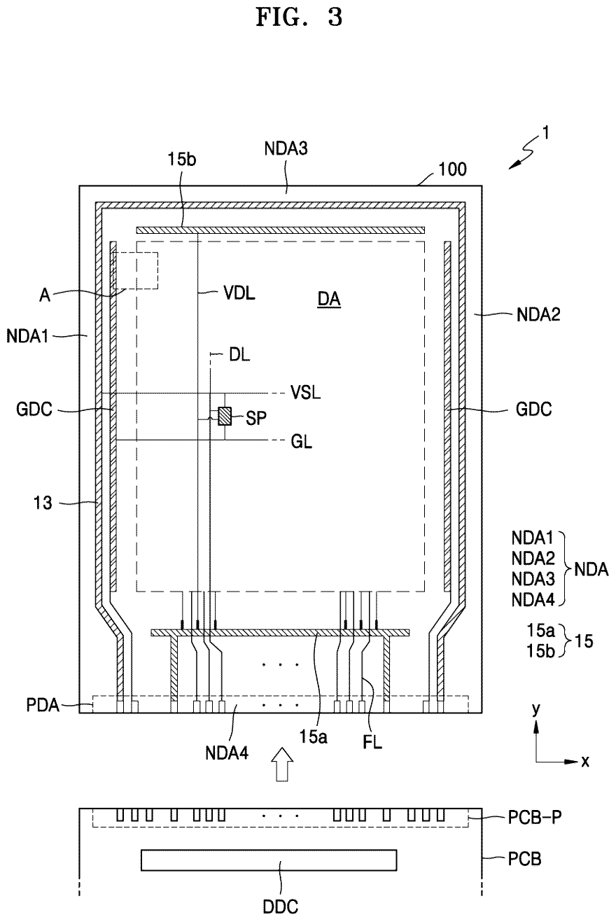

FIG. 3 is a plan view schematically illustrating the display device 1 according to one or more embodiments.

The display device 1 may include a display panel, and the display panel may include a substrate 100.

A plurality of sub-pixels SP and a plurality of conductive lines configured to provide electrical signals to the sub-pixels P may be arranged in the display area DA of the substrate 100. Each of the plurality of sub-pixels SP may emit, for example, red, green, blue, or white light through a light-emitting element. In this specification, a sub-pixel SP may be understood as a pixel that emits light of one of red, green, blue, and/or white, as described above. Each sub-pixel SP may be connected to a plurality of conductive lines. The plurality of conductive lines may include gate lines GL, data lines DL, driving voltage lines VDL, and common voltage lines VSL. Each sub-pixel SP may be electrically connected to peripheral circuits arranged in the non-display area NDA.

In the non-display area NDA, various conductive lines configured to transmit electrical signals to be applied to the display area DA, peripheral circuits electrically connected to pixel circuits, and pads to which printed circuit boards or driver integrated circuit (IC) chips are attached may be located. For example, a gate driver GDC, a terminal portion PDA, a driving voltage supply line 15, and a common voltage supply line 13 may be arranged in the non-display area NDA. In one or more embodiments, an initialization voltage supply line may be additionally arranged in the non-display area NDA.

The gate driver GDC may be arranged in each of a first non-display area NDA1 and a second non-display area NDA2, which are respectively arranged on two sides of the display area DA. The gate driver GDC may be connected to gate lines arranged in the display area DA. FIG. 3 shows that the gate driver GDC is arranged in each of the first non-display area NDA1 and the second non-display area NDA2, but the disclosure is not limited thereto. In one or more other embodiments, the gate driver GDC may be arranged in one of the first non-display area NDA1 or the second non-display area NDA2. A portion or all of the gate driver GDC may be formed directly in the non-display area NDA during the process of forming transistors constituting a pixel circuit in the display area DA.

A data driver DDC may be arranged in a third non-display area NDA3 and/or a fourth non-display area NDA4 that connect the first non-display area NDA1 and the second non-display area NDA2 to each other. In one or more embodiments, FIG. 3 shows that the data driver DDC arranged in the fourth non-display area NDA4. In one or more other embodiments, the data driver DDC may be arranged in each of the third non-display area NDA3 and the fourth non-display area NDA4.

The data driver DDC may be formed in the form of an IC chip. In one or more embodiments, as shown in FIG. 3, the data driver DDC may be arranged on a printed circuit board PCB, and a terminal portion PCB-P of the printed circuit board PCB may be electrically connected to the terminal portion PDA arranged in the fourth non-display area NDA4 of the substrate 100. In one or more other embodiments, the data driver DDC may be directly arranged in the fourth non-display area NDA4 of the substrate 100 in a chip-on-glass (COG) or chip-on-plastic (COP) manner.

The driving voltage supply line 15 may include a first sub-line 15a and a second sub-line 15b that extend in the first direction (e.g., the x-direction) in the fourth non-display area NDA4 and the third non-display area NDA3, respectively. The driving voltage supply line 15 may be connected to the driving voltage lines VDL of the display area DA.

The common voltage supply line 13 may have a loop shape with one open side, and may be arranged in the first non-display area NDA1, the second non-display area NDA2, and the third non-display area NDA3 to partially surround the display area DA. The common voltage supply line 13 may be connected to the common voltage lines VSL of the display area DA.

An elongation (e.g., a change in length, or an elongation rate) of the non-display area NDA may be equal to or less than the elongation of the display area DA. In one or more embodiments, the non-display area NDA may have a different elongation for each area. For example, the first non-display area NDA1, the second non-display area NDA2, and the third non-display area NDA3 may have substantially the same elongation, while the fourth non-display area NDA4 may have an elongation that is less than those of the first non-display area NDA1, the second non-display area NDA2, and the third non-display area NDA3. The term “elongation” as used herein refers to a numerical value representing a change in length (ΔL/L) by which the display device 1 may be stretched without physical damage to the display device 1 when an external force is applied to the display device 1. Here, ΔL indicates the amount of change in the length of the display device 1, and L indicates the initial length of the display device 1.

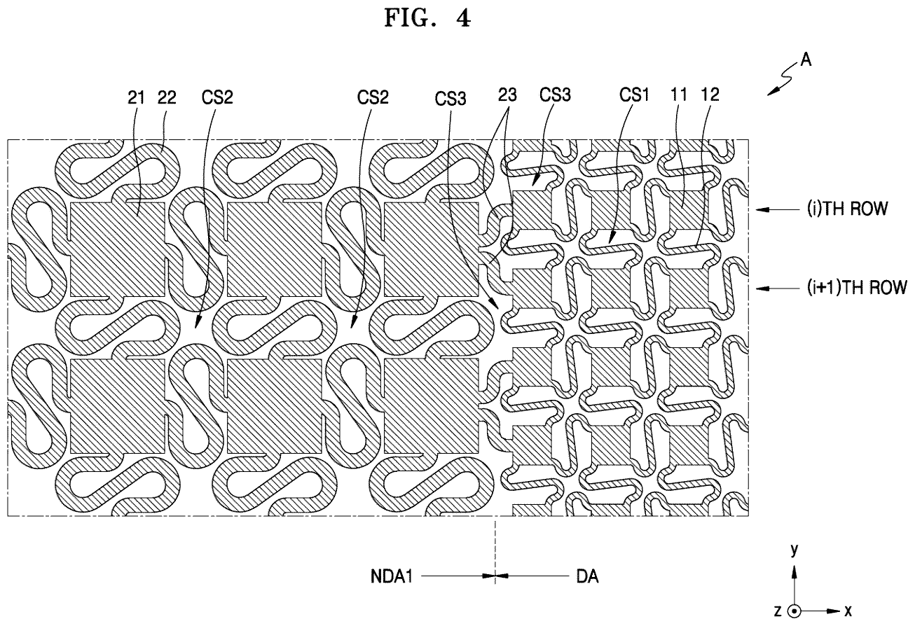

FIG. 4 is an enlarged plan view of region A of FIG. 3 as a portion of the display device 1 according to one or more embodiments.

Referring to FIG. 4, the display device 1 may include first island portions 11 separated from each other in the first direction (e.g., the x-direction or the −x-direction) and the second direction (e.g., the y-direction or the −y-direction) in the display area DA, and first bridge portions 12 connecting adjacent ones of the first island portions 11 to each other.

Each first island portion 11 may be connected to a plurality of first bridge portions 12. For example, the first island portion 11 may be connected to four first bridge portions 12. Two of the four first bridge portions 12 may be respectively arranged on two sides of the first island portion 11 generally in the first direction (e.g., the x-direction or the −x-direction), and the remaining two of the four first bridge portions 12 may be respectively arranged on two sides of the first island portion 11 generally in the second direction (e.g., the y-direction or the −y-direction). The four first bridge portions 12 may be respectively connected to four sides and/or corners of the first island portion 11. The four first bridge portions 12 may be respectively adjacent to corners of the first island portion 11.

The first bridge portions 12 may be separated from each other by a first opening CS1 located therebetween. Two ends of each first bridge portion 12 may be respectively connected to adjacent ones of the first island portions 11, and one side of each first bridge portion 12 may be separated from one side of one of the adjacent ones of the first island portions 11 and/or one side of another first bridge portion 12 by the first opening CS1.

The display device 1 may include second island portions 21 separated from each other in the first direction (e.g., the x-direction or the −x-direction) and the second direction (e.g., the y-direction or the −y-direction) in a non-display area, for example, the first non-display area NDA1 shown in FIG. 3, and also may include second bridge portions 22 connecting adjacent ones of the second island portions 21 to each other.

Each second island portion 21 may be connected to a plurality of second bridge portions 22. Each second island portion 21 may be connected to four second bridge portions 22. Two of the four second bridge portions 22 may be respectively arranged on two sides of the second island portion 21 generally in the first direction (e.g., the x-direction or the −x-direction), and the remaining two of the four second bridge portions 22 may be respectively arranged on two sides of the second island portion 21 generally in the second direction (e.g., the y-direction or the −y-direction). In one or more embodiments, the four second bridge portions 22 may be respectively connected to four sides of the second island portion 21.

The second island portions 21 arranged in one row in the first non-display area NDA1 may correspond to the first island portions 11 arranged in at least one row in the display area DA. For example, the second island portions 21 arranged in one row in the first non-display area NDA1 may correspond to the first island portions 11 arranged in k rows (where k is a positive number greater than or equal to 2). FIG. 4 shows an example in which the second island portions 21 arranged in one row in the first non-display area NDA1 correspond to the first island portions 11 arranged in an (i)th row and the first island portions 11 arranged in an (i+1)th row in the display area DA (where i is a positive number greater than 0). In another example, the second island portions 21 arranged in the (i)th row in the first direction (for example, the x-direction or the −x-direction) in the first non-display area NDA1 may correspond to the first island portions 11 arranged in the same row, for example, the (i)th row, in the display area DA (where i is a positive number greater than 0).

The second bridge portions 22 may be separated from each other by a second opening CS2 located between the second bridge portions 22. Two ends of each second bridge portion 22 may be respectively connected to adjacent ones of the second island portions 21, and one side of each second bridge portion 22 may be separated from one side of one of the adjacent ones of the second island portions 21 and/or one side of another second bridge portion 22 by the second opening CS2.

Third bridge portions 23 for connecting the first island portion 11 of the display area DA and the second island portion 21 of the first non-display area NDA1 to each other may be arranged in a boundary area between the display area DA and the first non-display area NDA1. Each third bridge portion 23 may extend in the first direction (e.g., the x-direction or the −x-direction), one end of the third bridge portion 23 may be connected to one side of the second island portion 21, and the other end of the third bridge portion 23 may be connected to one side of the first island portion 11. The third bridge portions 23 may be separated from each other by a third opening CS3 located between the third bridge portions 23.

In one or more embodiments, the first bridge portion 12, the second bridge portion 22, and the third bridge portion 23 may each have a straight shape or a winding shape, such as a serpentine shape, a sine wave shape, or a letter S shape. The shapes of the first bridge portion 12, the second bridge portion 22, and the third bridge portion 23 may be the same as or different from each other.

The size and/or width of the second bridge portion 22 may be the same as or different from the size and/or width of the first bridge portion 12. For example, the size and/or width of the second bridge portion 22 may be greater than the size and/or width of the first bridge portion 12. The radius of curvature of a round portion of the second bridge portion 22 may be different from the radius of curvature of a round portion of the first bridge portion 12. For example, the radius of curvature of a round portion of the second bridge portion 22 may be greater than the radius of curvature of a round portion of the first bridge portion 12. The width of the third bridge portion 23 may be the same as or different from the width of the first bridge portion 12 and the width of the second bridge portion 22. For example, the width of the third bridge portion 23 may be greater than the width of the first bridge portion 12, and less than the width of the second bridge portion 22.

FIG. 4 shows that the second island portion 21 and the second bridge portion 22 of a non-display area, for example, the first non-display area NDA1, have the same shapes as the first island portion 11 and the first bridge portion 12 of the display area DA, respectively. In one or more other embodiments, the second island portion 21 and the second bridge portion 22 of the non-display area may have different shapes from the first island portion 11 and the first bridge portion 12 of the display area DA, respectively.

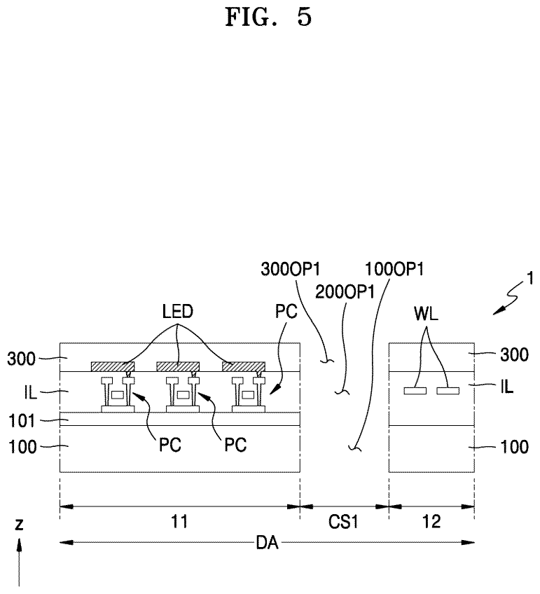

FIG. 5 is a cross-sectional view schematically illustrating the first island portion 11 and the first bridge portion 12 that are arranged in the display area DA of the display device 1, according to one or more embodiments.

Referring to FIG. 5, the first island portion 11 and the first bridge portion 12, which are arranged in the display area DA, may be separated from each other with the first opening CS1 therebetween. Light-emitting elements LED and pixel circuits PC respectively electrically connected to the light-emitting elements LED may be arranged in the first island portion 11, and conductive lines WL respectively electrically connected to the pixel circuits PC arranged in each of adjacent ones of the first island portions 11 may be arranged in the first bridge portion 12.

In the first island portion 11, a barrier layer 101 including an inorganic insulating material may be arranged on the substrate 100, and the pixel circuit PC may be arranged on the barrier layer 101. An insulating layer IL including an inorganic insulating material and/or an organic insulating material may be arranged between the pixel circuit PC and the light-emitting element LED. The light-emitting element LED may be arranged on the insulating layer IL, and may be electrically connected to the pixel circuit PC corresponding to the light-emitting element LED. The light-emitting elements LED may emit light of different colors or light of the same color. In one or more embodiments, the light-emitting elements LED may respectively emit red light, green light, and blue light. In some embodiments, the light-emitting elements LED may emit white light. In one or more other embodiments, the light-emitting elements LED may respectively emit red light, green light, blue light, and white light.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In one or more embodiments, the substrate 100 may be a single layer including the above-described polymer resin. In one or more other embodiments, the substrate 100 may have a multi-layer structure including a base layer including the above-described polymer resin and a barrier layer including an inorganic insulating material. For example, the substrate 100 may have a structure in which a first base layer, a barrier layer, and a second base layer are sequentially stacked. The substrate 100 may be flexible, rollable, or bendable.

In one or more embodiments, FIG. 5 shows three pixel circuits PC arranged in each first island portion 11 and three light-emitting elements LED respectively connected to the pixel circuits PC, but the disclosure is not limited thereto. In one or more other embodiments, the number of pixel circuits PC and the number of light-emitting elements LED arranged in the first island portion 11 may each be one, two, or four or more.

An encapsulation layer 300 may be arranged on the light-emitting element LED, and may protect the light-emitting element LED from an external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In one or more other embodiments, the encapsulation layer 300 may include an organic material, such as resin. In some embodiments, the encapsulation layer 300 may include urethane epoxy acrylate. The encapsulation layer 300 may include a photosensitive material, for example, photoresist.

In the first bridge portion 12, the insulating layer IL including an organic insulating material may be arranged on the substrate 100. When the display device 1 is stretched, the first bridge portion 12, which is subject to relatively high deformation, may not have a layer including an inorganic insulating material that is prone to cracking, unlike the first island portion 11.

In one or more embodiments, the substrate 100 corresponding to the first bridge portion 12 may have a stacked structure that is identical to that of the substrate 100 corresponding to the first island portion 11. In one or more embodiments, the substrate 100 corresponding to the first bridge portion 12, and the substrate 100 corresponding to the first island portion 11, may be polymer resin layers that are formed together in the same process. In one or more other embodiments, the substrate 100 corresponding to the first bridge portion 12 may have a stacked structure that is different from that of the substrate 100 corresponding to the first island portion 11. In some embodiments, the substrate 100 corresponding to the first bridge portion 12 may have a multi-layer structure including a base layer including polymer resin and a barrier layer including an inorganic insulating material, and the substrate 100 corresponding to the first bridge portion 12 may have a structure including a polymer resin layer without a layer including an inorganic insulating material.

The conductive lines WL of the first bridge portion 12 may be signal lines (e.g. gate lines, data lines, driving voltage lines, common voltage lines, initialization voltage lines, voltage connection lines, etc.) configured to provide electrical signals to transistors included in the pixel circuit PC of the first island portion 11. The encapsulation layer 300 may also be arranged in the first bridge portion 12. In one or more other embodiments, the encapsulation layer 300 may not be present in the first bridge portion 12.

The substrate 100, the barrier layer 101, the insulating layer IL, and the encapsulation layer 300 may each include an area corresponding to the first island portion 11, an area corresponding to the first bridge portion 12, and an opening corresponding to the first opening CS1. Each of an opening 100OP1 of the substrate 100, an opening 200OP1 of the barrier layer 101 and the insulating layer IL, and an opening 300OP1 of the encapsulation layer 300 may overlap the first opening CS1, and may have a shape that is similar to that of the first opening CS1.

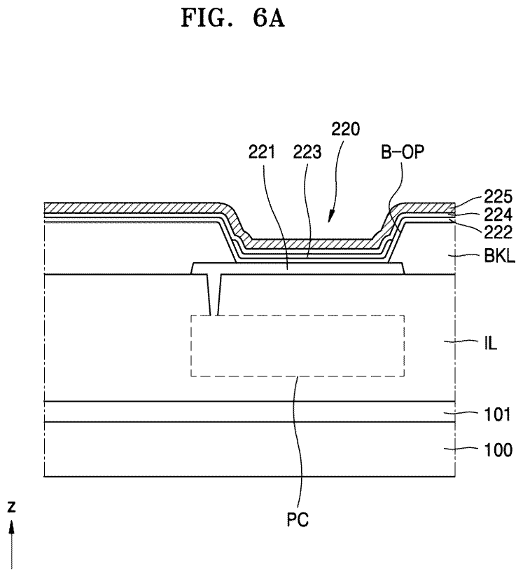

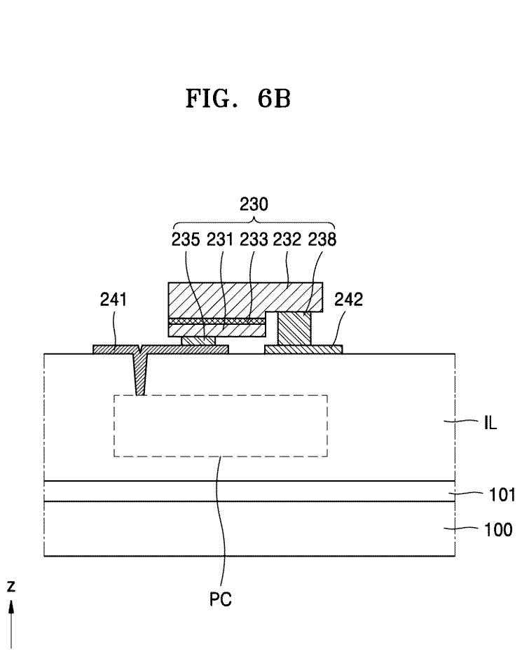

FIG. 6A is a cross-sectional view schematically illustrating a light-emitting element of the display device 1 according to one or more embodiments.

Referring to FIG. 6A, the light-emitting element LED (see FIG. 5) according to one or more embodiments may include an organic light-emitting diode 220 including an organic material. The organic light-emitting diode 220 may include a first electrode 221 arranged on the insulating layer IL, a second electrode 225 facing the first electrode 221, and an emission layer 223 arranged between the first electrode 221 and the second electrode 225. A first functional layer 222 may be arranged between the first electrode 221 and the emission layer 223. A second functional layer 224 may be arranged between the emission layer 223 and the second electrode 225. The first electrode 221 may be connected to the pixel circuit PC.

An edge of the first electrode 221 may be covered by a bank layer BKL including an insulating material. The bank layer BKL may include an opening B-OP overlapping a portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more other embodiments, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In one or more other embodiments, the first electrode 221 may further include a layer including ITO, IZO, ZnO, AZO, or In₂O₃ above/below the above-described reflective layer.

The emission layer 223 may include a polymer or low-molecular weight organic material that emits light of a corresponding color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. For example, the second electrode 225 may include a (semi-)transparent layer including Ag, Mg, Al, Pt, Pd, Au, Ni, Nd, Ir, Cr, lithium (Li), calcium (Ca), or an alloy thereof. Alternatively, the second electrode 225 may include a layer including ITO, IZO, ZnO, AZO, or In₂O₃ on the (semi-)transparent layer including the above-described material.

FIG. 6B is a cross-sectional view schematically illustrating a light-emitting element of the display device 1 according to one or more embodiments.

Referring to FIG. 6B, the light-emitting element LED according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are arranged on the same layer. The first electrode pad 241 may be connected to the pixel circuit PC.

In some embodiments, the first semiconductor layer 231 may include a p-type semiconductor layer. The p-type semiconductor layer may include a semiconductor material having a composition formula of InₓAl_{y}Ga_{1-x-y}N (where 0≤x≤1, 0≤y≤1, and 0≤x+y≤1), for example, a semiconductor material selected from GaN, AlN, AlGaN, InGaN, InN, InAlGaN, and/or AlInN, and may be doped with a p-type dopant, such as Mg, Zn, Ca, Sr, or Ba.

The second semiconductor layer 232 may include, for example, an n-type semiconductor layer. The n-type semiconductor layer may include a semiconductor material having a composition formula of InₓAl_{y}Ga_{1-x-y}N (where 0≤x≤1, 0≤y≤1, and 0≤x+y≤1), for example, a semiconductor material selected from GaN, AlN, AlGaN, InGaN, InN, InAlGaN, and/or AlInN, and may be doped with an n-type dopant, such as Si, Ge, or Sn.

The intermediate layer 233 may be an area in which electrons and holes recombine, may transition to a low energy level as the electrons and holes recombine, and may generate light having a corresponding wavelength. For example, the intermediate layer 233 may include a semiconductor material having a composition formula of InₓAl_{y}Ga_{1-x-y}N (where 0≤x≤1, 0≤y≤1, and 0≤x+y≤1), and may be formed in a single quantum well structure or a multi quantum well (MQW) structure. In addition, the intermediate layer 233 may include a quantum wire structure or a quantum dot structure.

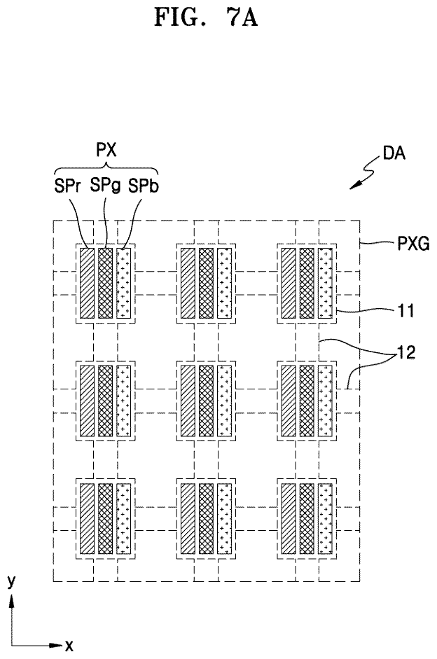

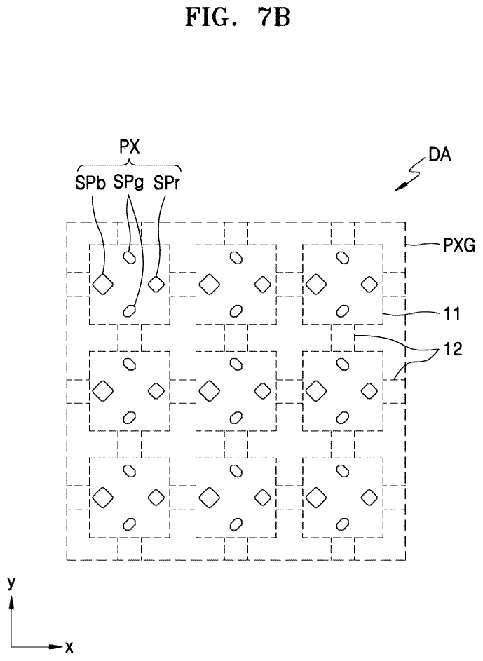

FIGS. 7A and 7B are diagrams schematically illustrating a portion of the display area DA according to one or more embodiments.

A plurality of pixels PX may be arranged in the display area DA. A pixel PX may refer to a repeating unit of a sub-pixel including a plurality of sub-pixels SP that emit light of different colors. Each pixel PX may be arranged in one first island portion 11.

The plurality of sub-pixels SP may include a first sub-pixel that emits light of a first color, a second sub-pixel that emits light of a second color, and a third sub-pixel that emits light of a third color. For example, the first sub-pixel may be a red pixel SPr, the second sub-pixel may be a green pixel SPg, and the third sub-pixel may be a blue pixel SPb. The first sub-pixel, the second sub-pixel, and the third sub-pixel may each include a pixel circuit and a light-emitting element electrically connected to the pixel circuit. The pixel circuit may include a plurality of transistors and at least one capacitor, and may be a pixel driving circuit that controls driving of the light-emitting element.

The pixel PX may be a minimum repeating unit of the sub-pixels SP having a corresponding arrangement. The plurality of sub-pixels SP may be arranged in various forms, such as a stripe arrangement, a PenTile®/PENTILE™ arrangement (PenTile® and PENTILE™ being registered trademarks of Samsung Display Co., Ltd., Republic of Korea), a Diamond Pixel™ arrangement (Diamond Pixel™ being a registered trademark of Samsung Display Co., Ltd., Republic of Korea), and/or a mosaic arrangement, to implement an image. In one or more embodiments, a pixel or sub-pixel may refer to a light-emitting element, and the arrangement structure of sub-pixels may be understood as the arrangement structure of light-emitting elements. Hereinafter, the arrangement structure of sub-pixels may refer to the arrangement structure of light-emitting elements, and light emission of a pixel or sub-pixel may refer to light emission of a light-emitting element.

In one or more embodiments, as shown in FIG. 7A, the sub-pixels SP may be arranged in a stripe structure in the display area DA, and the pixel PX may include one red pixel SPr, one green pixel SPg, and one blue pixel SPb.

In one or more embodiments, as shown in FIG. 7B, the sub-pixels SP may be arranged in a PenTile® structure in the display area DA, and the pixel PX may include one red pixel SPr, two green pixels SPg, and one blue pixel SPb.

The sub-pixels SP in the pixel PX may be connected to the same gate line GL, and may respectively be connected to the data lines DL corresponding to the sub-pixels SP.

The display device 1 may control the number of pixels PX that emit light in a pixel group PXG, according to the degree of stretching of the display device 1. The pixel group PXG may include pixels PX of n×m (where n and m are each a positive number of 2 or more) or first island portions 11 of n×m. The degree of stretching may refer to a stretching rate indicating the degree to which the display device 1 is stretched and/or the degree to which the display device 1 is shrunk.

When the display device 1 is stretched, a distance between the pixels PX may increase, and the pixel distribution rate in the stretched area may decrease. When the display area DA is shrunk, the distance between the pixels PX may decrease, and the pixel distribution rate in the shrunk area may increase. Shrinking may include shrinking of the display device 1 before stretching and recovering of the display device 1 to its original state after stretching.

A non-stretched state of the display device 1 may refer to a state in which the degree of stretching is minimum, and when the display device 1 is in a stretched state, an increase in the degree of stretching may refer to an increase in the degree to which the display device 1 is stretched. Here, the stretched state may include a state after stretching of the display device 1 is completed, and a state in which the display device 1 is being stretched.

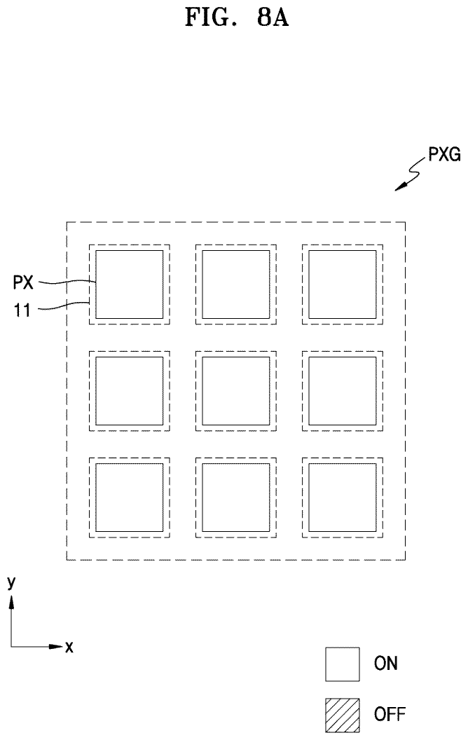

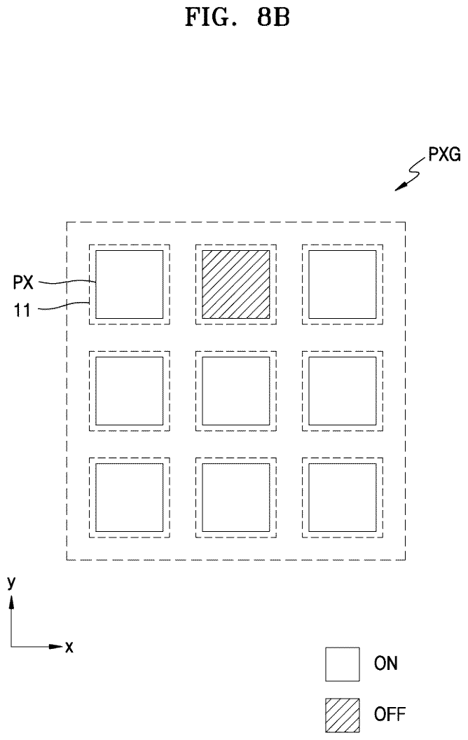

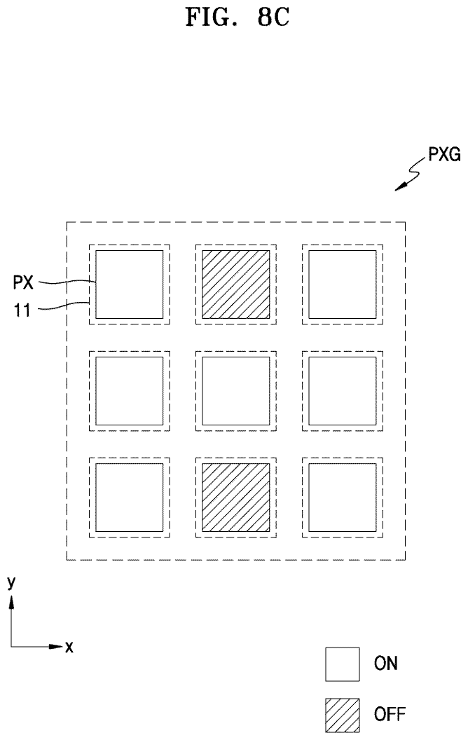

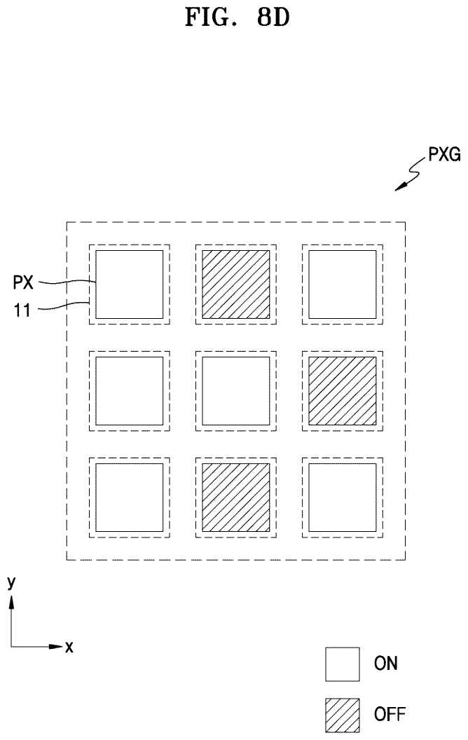

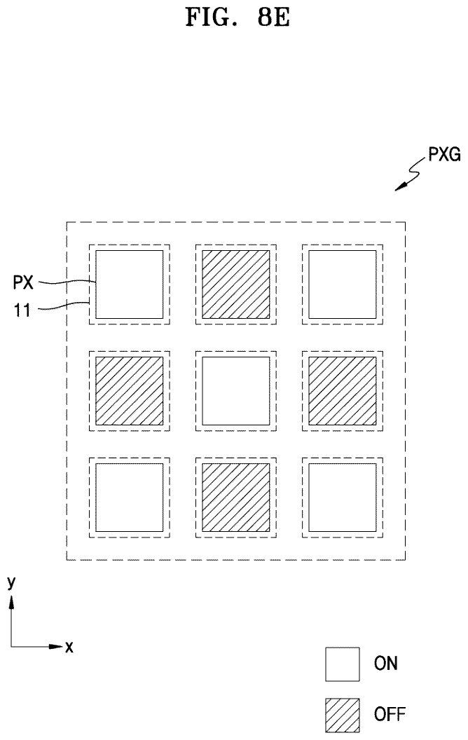

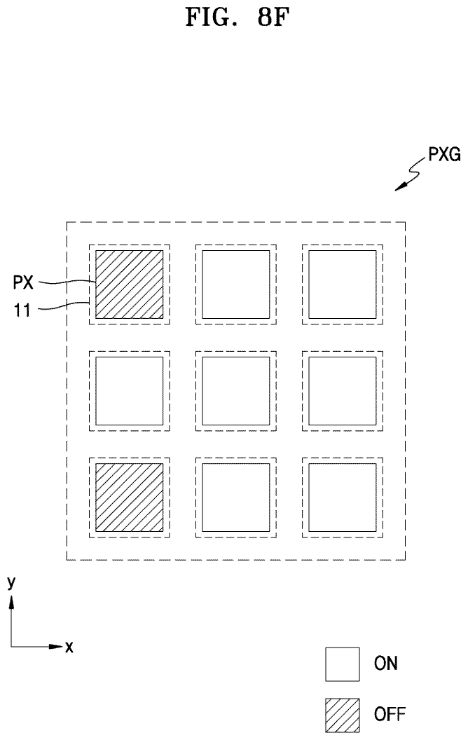

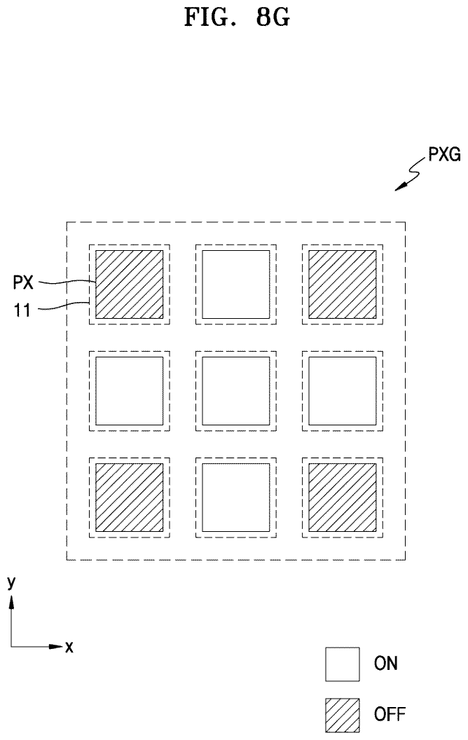

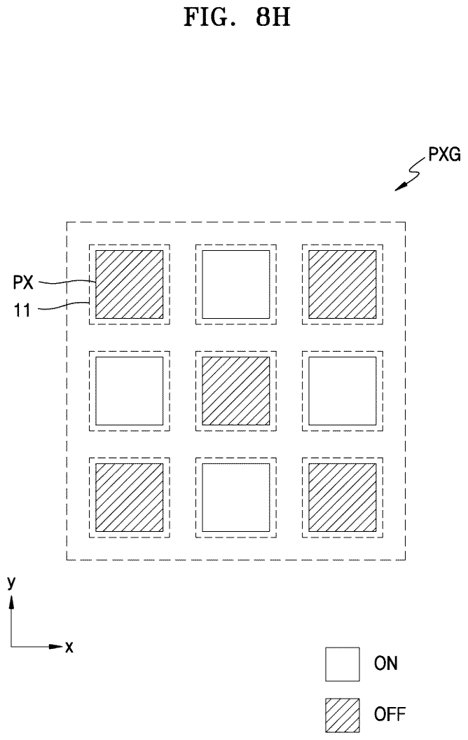

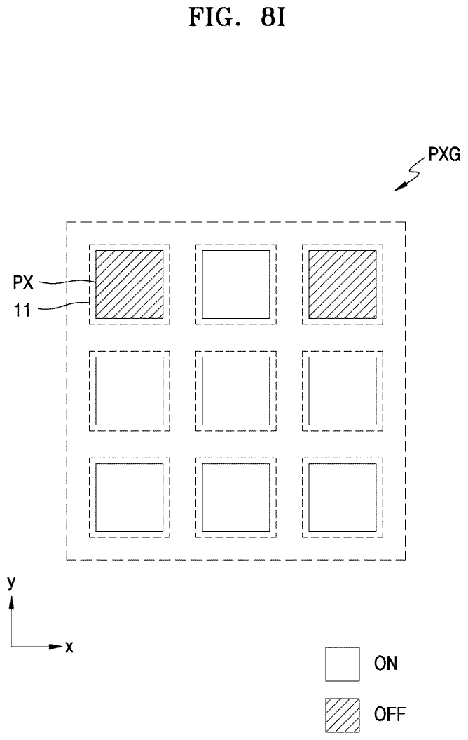

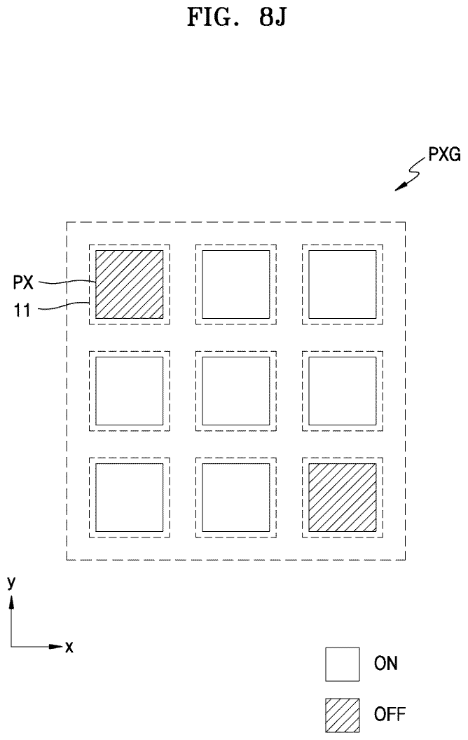

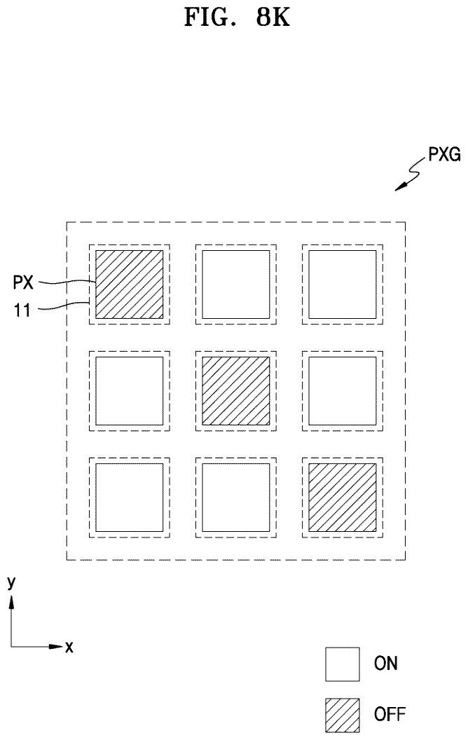

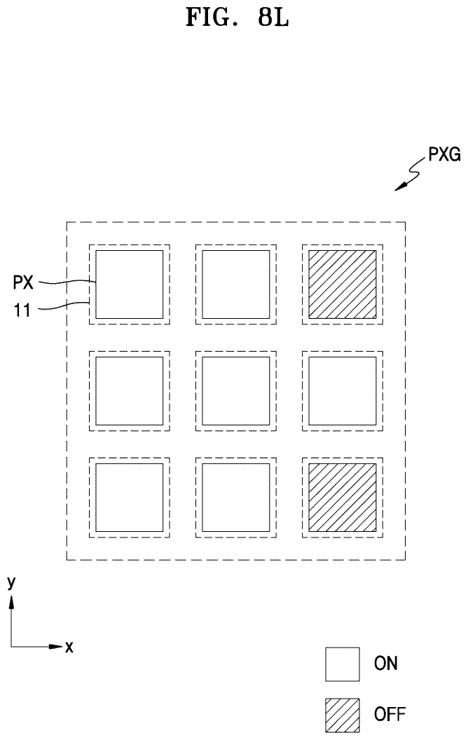

FIGS. 8A to 8L are diagrams illustrating a light emission state of the pixel PX constituting the pixel group PXG, according to one or more embodiments. Hereinafter, for convenience of illustration and description, the pixel PX that emits light is indicated as “on” in the drawings, and the pixel PX that does not emit light is indicated as “off” in the drawings.

FIGS. 8A to 8L show various examples in which, in the pixel group PXG including nine pixels PX (or nine first island portions 11) of 3×3, light emission of the pixels PX in the pixel group PXG is controlled according to the degree of stretching of the display device 1. As the degree of stretching of the display device 1 increases, the number of pixels PX that emit light may increase.

Because each of the pixels PX constituting the pixel group PXG is arranged in the first island portion 11, the pixel group PXG may be referred to as an island group, and the pixel arrangement structure may be referred to as an island arrangement structure.

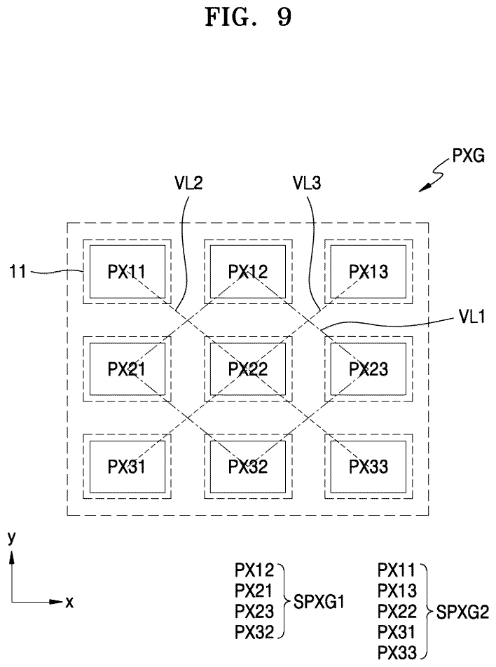

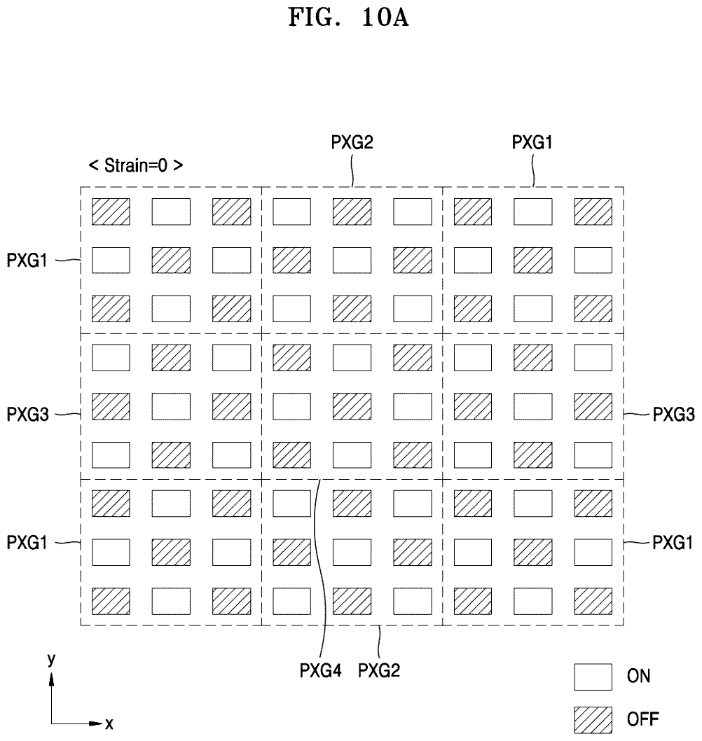

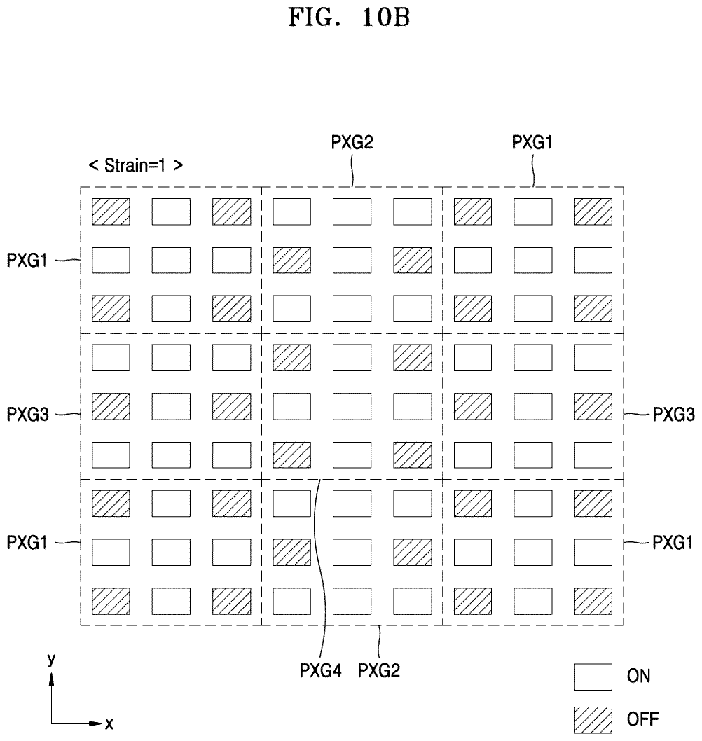

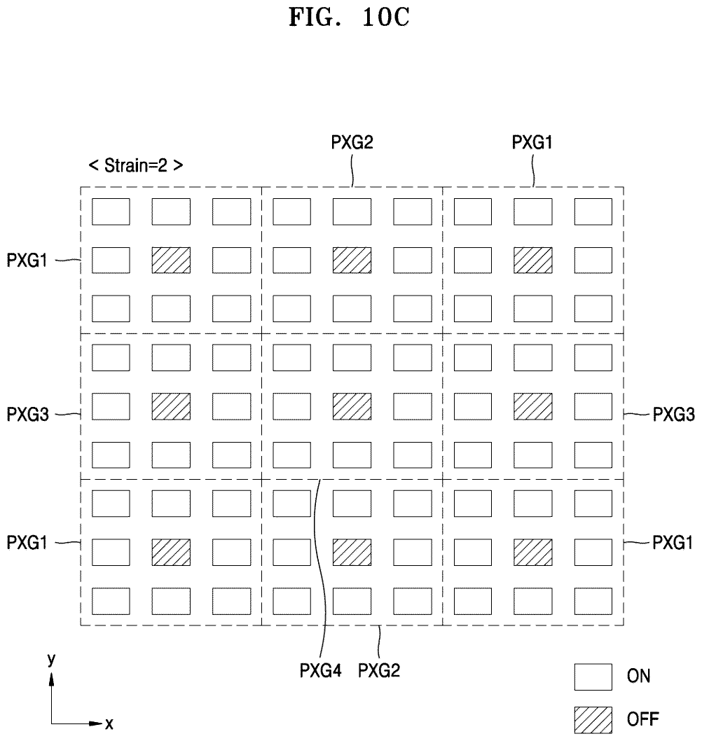

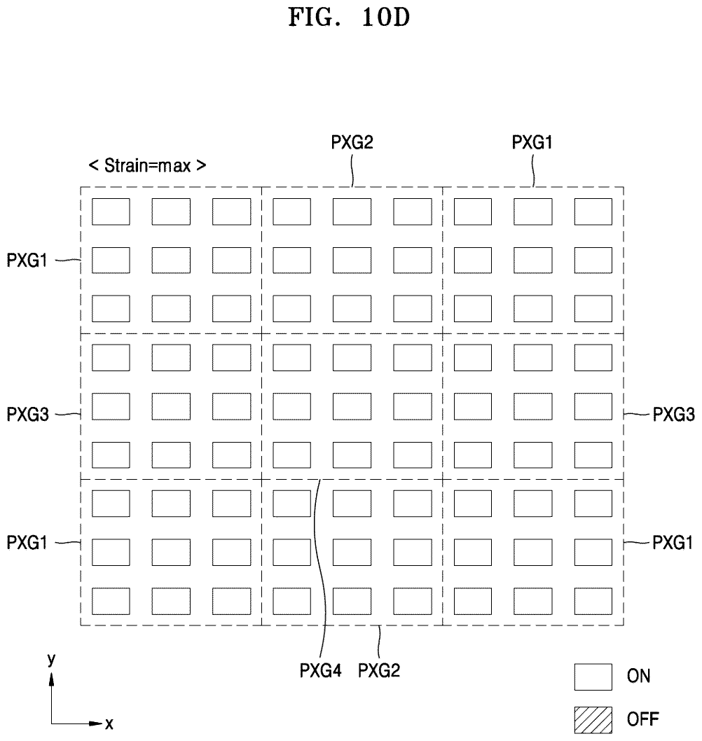

FIG. 9 is a diagram schematically illustrating the pixel group PXG according to one or more embodiments. FIGS. 10A to 10D are diagrams schematically illustrating a light emission state of the pixel group PXG at each stretching stage corresponding to the degree of stretching.

Referring to FIG. 9, the pixel group PXG may include nine pixels PX, that is, pixels PX11, PX12, PX13, PX21, PX22, PX23, PX31, PX32, and PX33, of 3×3. As the degree of stretching increases, the number of pixels PX that emit light in the pixel group PXG may increase, and a distance between the pixels PX may increase. In the drawings described below, for convenience of illustration and description, a change in the distance between the pixels PX according to the degree of stretching is omitted.

In one or more embodiments, the pixel group PXG may include a first sub-pixel group SPXG1 and a second sub-pixel group SPXG2. The first sub-pixel group SPXG1 may include the pixels PX12, PX21, PX23, and PX32 that overlap virtual lines VL1 forming a diamond shape. The second sub-pixel group SPXG2 may include the pixels PX11, PX13, PX22, PX31, and PX33 that overlap virtual lines VL2 and VL3 forming an X shape.

In a non-stretched state (e.g., Strain=0, and/or a first display mode), the first sub-pixel group SPXG1 or the second sub-pixel group SPXG2 in each pixel group PXG may emit light. For example, as shown in FIG. 10A, the pixel groups PXG in which the first sub-pixel group SPXG1 emits light and in which the second sub-pixel group SPXG2 does not emit light, and the pixel groups PXG in which the first sub-pixel group SPXG1 does not emit light and in which the second sub-pixel group SPXG2 emits light, may be alternately located in the first direction (the x-direction or the −x-direction) and in the second direction (the y-direction or the −y-direction). Accordingly, in the first display mode, the pixel PX that emits light and the pixel PX that does not emit light may be located in a grid shape.

In the first display mode, for every four pixel groups PXG, four pixels PX (e.g., the pixels PX12, PX21, PX23, and PX32, as shown in FIG. 9) among nine pixels PX may emit light in a first pixel group PXG1 and in a fourth pixel group PXG4, and five pixels PX (e.g., the pixels PX11, PX13, PX22, PX31, and PX33, as shown in FIG. 9) among nine pixels PX may emit light in a second pixel group PXG2 and in a third pixel group PXG3.

In a state in which the degree of stretching is 1 (e.g., Strain=1, and/or a second display mode), the number of pixels PX that emit light in each pixel group PXG may be greater than the number of pixels PX that emit light in each pixel group PXG in the first display mode. In one or more embodiments, at least one of the pixels PX that do not emit light in the first display mode may emit light. For example, in the second display mode, for every four pixel groups PXG, at least one of the pixels PX of the second sub-pixel group SPXG2 that do not emit light in the first pixel group PXG1 and in the fourth pixel group PXG4, and/or at least one of the pixels PX of the first sub-pixel group SPXG1 that do not emit light in the second pixel group PXG2 and in the third pixel group PXG3, may emit light.

As shown in FIG. 10B, in the second display mode, for every four pixel groups PXG, five pixels PX (e.g., the pixels PX12, PX21, PX22, PX23, and PX32, as shown FIG. 9) among nine pixels PX may emit light in the first pixel group PXG1 and in the fourth pixel group PXG4, and seven pixels PX (e.g., the pixels PX11, PX12, PX13, PX22, PX31, PX32, and PX33, as shown in FIG. 9) among nine pixels PX may emit light in the second pixel group PXG2 and in the third pixel group PXG3.

In a state in which the degree of stretching is 2 (e.g., Strain=2, and/or a third display mode), the number of pixels PX that emit light in each pixel group PXG may be greater than the number of pixels PX that emit light in each pixel group PXG in the second display mode. In one or more embodiments, at least one of the pixels PX that do not emit light in the second display mode may emit light, and at least one of the pixels PX that emit light in the second display mode may not emit light. In each pixel group PXG, at least one of the pixels PX of the first sub-pixel group SPXG1 or of the second sub-pixel group SPXG2 that emit light may not emit light, and/or at least one of the pixels PX of the first sub-pixel group SPXG1 or of the second sub-pixel group SPXG2 that do not emit light may emit light.

For example, as shown in FIG. 10C, in the third display mode, the pixel PX located at the center in each pixel group PXG may not emit light, and the remaining pixels PX may emit light. In the third display mode, eight pixels PX (e.g., the pixels PX11, PX12, PX13, PX21, PX23, PX31, PX32, and PX33, as shown in FIG. 9) among the nine pixels PX in each pixel group PXG may emit light.

In a state in which the degree of stretching is maximum (e.g., Strain=max, and/or a fourth display mode), the number of pixels PX that emit light in each pixel group PXG may be greater than the number of pixels PX that emit light in each pixel group PXG in the third display mode.

For example, as shown in FIG. 10D, in the fourth display mode, all pixels PX in each pixel group PXG may emit light.

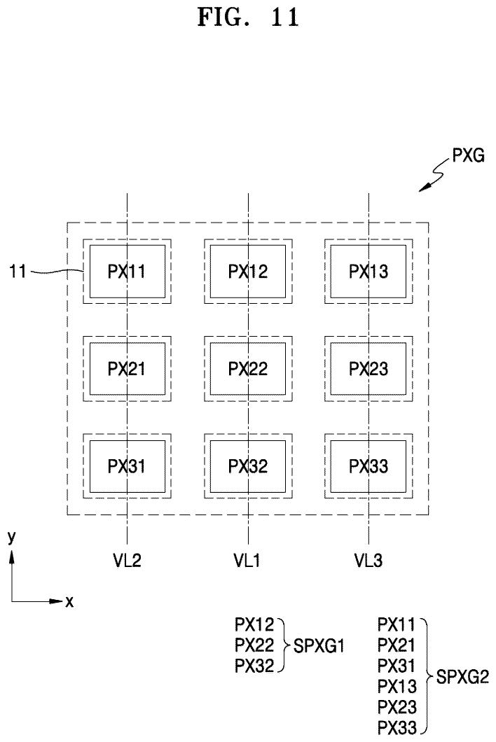

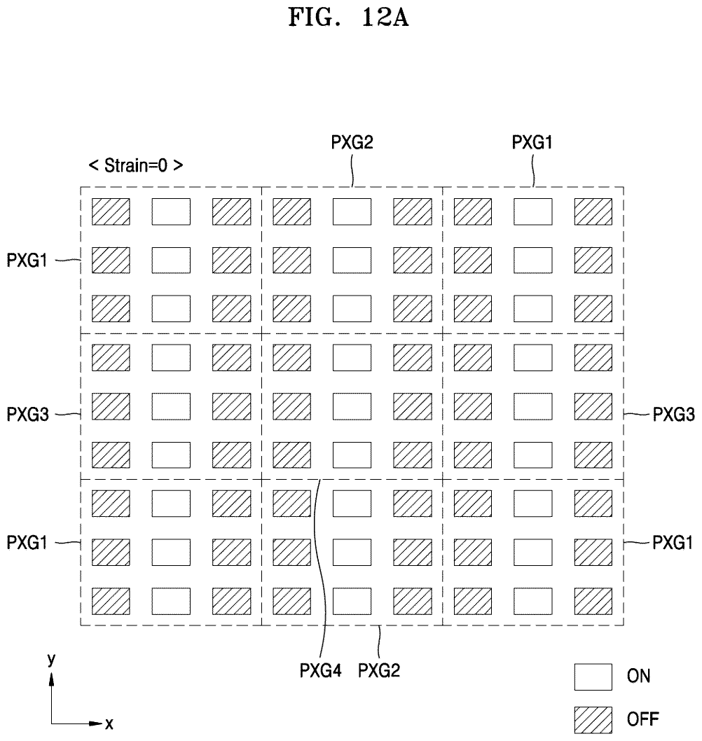

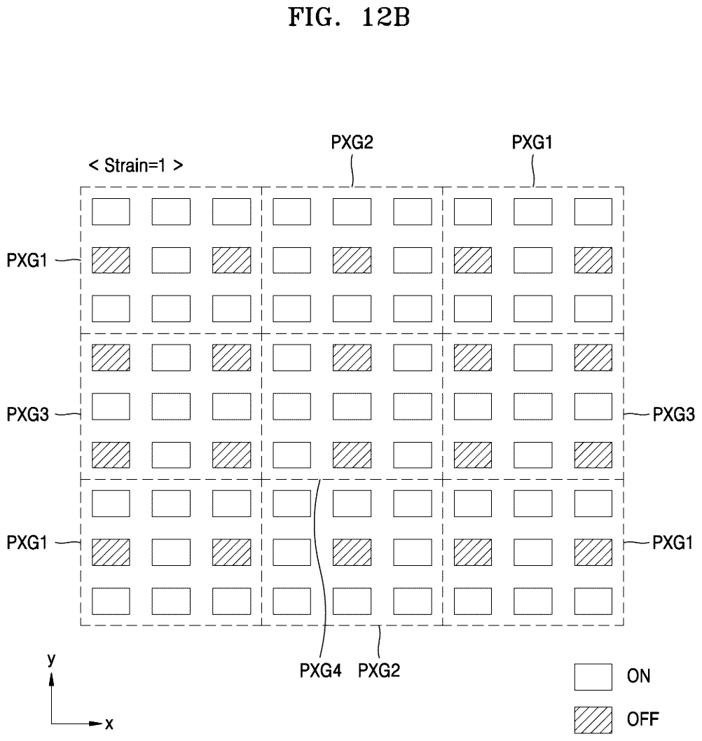

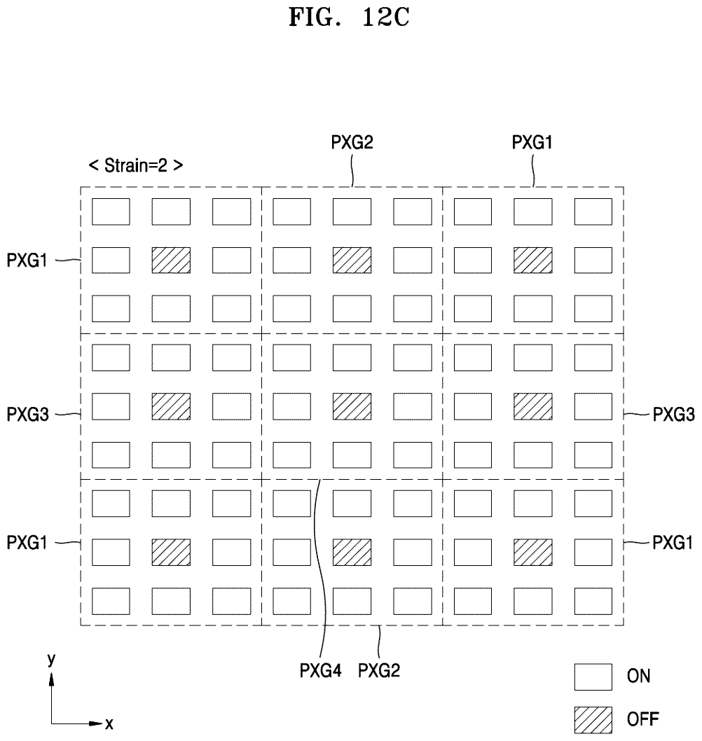

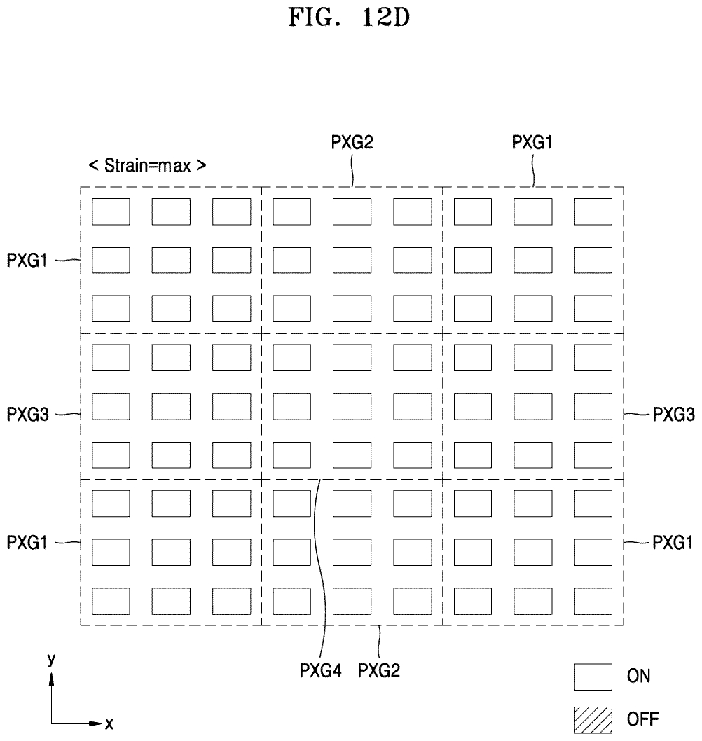

FIG. 11 is a diagram schematically illustrating the pixel group PXG according to one or more embodiments. FIGS. 12A to 12D are diagrams schematically illustrating a light emission state of the pixel group PXG according to the degree of stretching.

Referring to FIG. 11, the pixel group PXG may include nine pixels PX, that is, pixels PX11, PX12, PX13, PX21, PX22, PX23, PX31, PX32, and PX33, of 3×3.

In one or more embodiments, the pixel group PXG may include a first sub-pixel group SPXG1 and a second sub-pixel group SPXG2. The first sub-pixel group SPXG1 may include the pixels PX12, PX22, and PX32 that overlap a virtual line VL1 along a central column (an even column), among the nine pixels PX (e.g., the pixels PX11, PX12, PX13, PX21, PX22, PX23, PX31, PX32, and PX33) of 3×3. The second sub-pixel group SPXG2 may include the pixels PX11, PX21, PX31, PX13, PX23, and PX33 that overlap virtual lines VL2 and VL3 along left and right columns (odd columns), among the nine pixels PX.

In a non-stretched state (e.g., Strain=0, and/or a first display mode), the first sub-pixel group SPXG1 or the second sub-pixel group SPXG2 in each pixel group PXG may emit light. For example, as shown in FIG. 12A, the first sub-pixel group SPXG1 in each pixel group PXG may emit light, and the second sub-pixel group SPXG2 in each pixel group PXG may not emit light. In the first display mode, among the nine pixels PX in each pixel group PXG, three pixels PX of the first sub-pixel group SPXG1 may emit light.

In a state in which the degree of stretching is 1 (e.g., Strain=1, and/or a second display mode), the number of pixels PX that emit light in each pixel group PXG may be greater than the number of pixels PX that emit light in each pixel group PXG in the first display mode. In one or more embodiments, at least one of the pixels PX that do not emit light in the first display mode may emit light, and at least one of the pixels PX that emit light in the first display mode may not emit light. For example, in each pixel group PXG, at least one of the pixels PX of the first sub-pixel group SPXG1 that emit light may not emit light, and/or at least one of the pixels PX of the second sub-pixel group SPXG2 that do not emit light may emit light.

As shown in FIG. 12B, in the second display mode, for every four pixel groups PXG, seven pixels PX (e.g., the pixels PX11, PX12, PX13, PX22, PX31, PX32, and PX33, as shown FIG. 11) among nine pixels PX may emit light in a first pixel group PXG1, eight pixels PX (e.g., the pixels PX11, PX12, PX13, PX21, PX23, PX31, PX32, and PX33, as shown FIG. 11) among nine pixels PX may emit light in a second pixel group PXG2, five pixels PX (e.g., the pixels PX12, PX21, PX22, PX23, and PX32, as shown in FIG. 11) among nine pixels PX may emit light in a third pixel group PXG3, and seven pixels PX (e.g., the pixels PX11, PX13, PX21, PX22, PX23, PX31, and PX33, as shown in FIG. 11) among nine pixels PX may emit light in a fourth pixel group PXG4.

In a state in which the degree of stretching is 2 (e.g., Strain=2, and/or a third display mode), the number of pixels PX that emit light in each pixel group PXG may be greater than the number of pixels PX that emit light in each pixel group PXG in the second display mode. In one or more embodiments, at least one of the pixels PX that do not emit light in the second display mode may emit light, and at least one of the pixels PX that emit light in the second display mode may not emit light. In each pixel group PXG, at least one of the pixels PX of the first sub-pixel group SPXG1 or the second sub-pixel group SPXG2 that emit light may not emit light, and/or at least one of the pixels PX of the first sub-pixel group SPXG1 or the second sub-pixel group SPXG2 that do not emit light may emit light. For example, as shown in FIG. 12C, in the third display mode, the pixel PX located at the center in each pixel group PXG may not emit light, and the remaining pixels PX may emit light. In the third display mode, eight pixels PX (e.g., the pixels PX11, PX12, PX13, PX21, PX23, PX31, PX32, and PX33, as shown in FIG. 11) among the nine pixels PX in each pixel group PXG may emit light.

In a state in which the degree of stretching is maximum (e.g., Strain=max, and/or a fourth display mode), the number of pixels PX that emit light in each pixel group PXG may be greater than the number of pixels PX that emit light in each pixel group PXG in the third display mode. For example, as shown in FIG. 12D, in the fourth display mode, all pixels PX in each pixel group PXG may emit light.

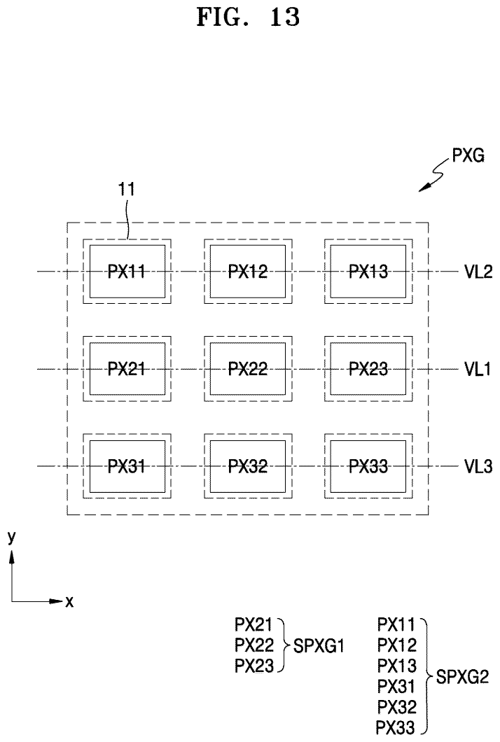

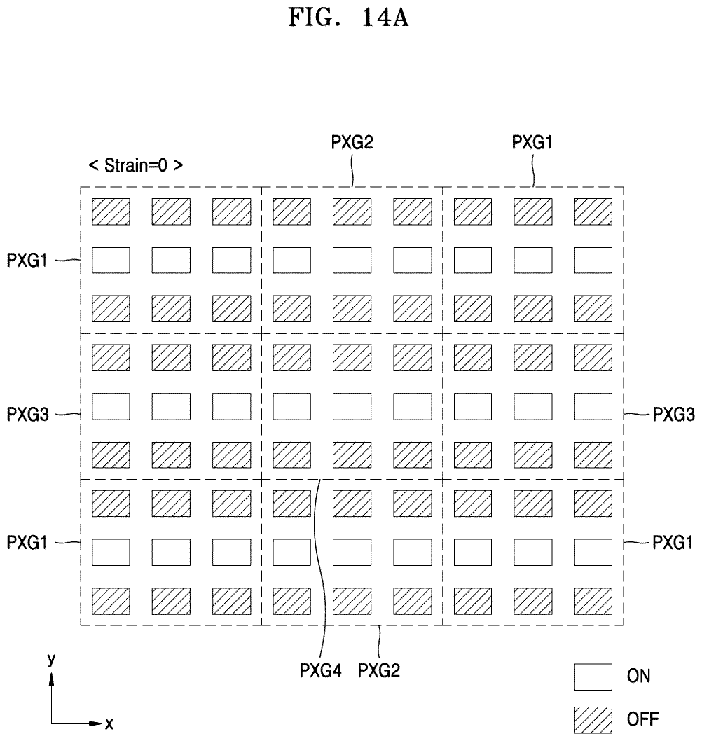

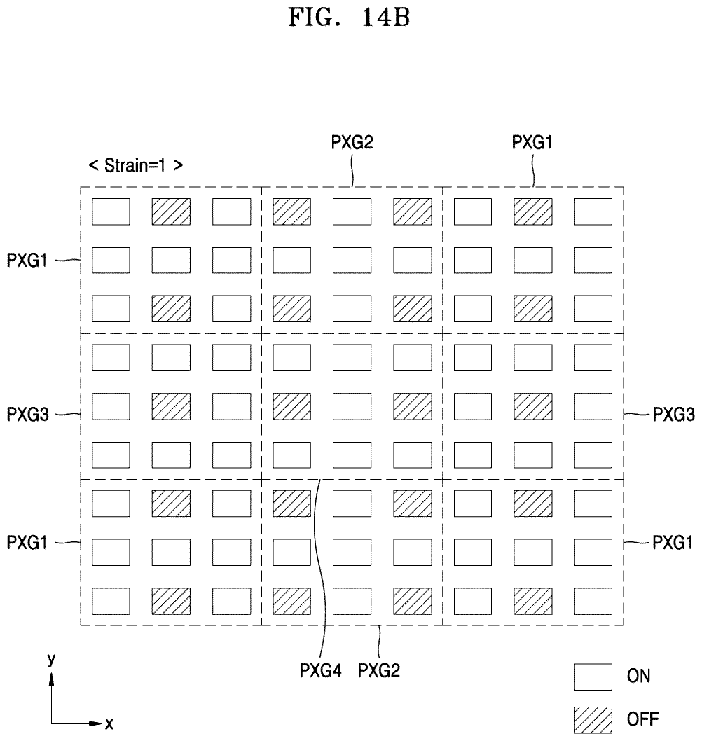

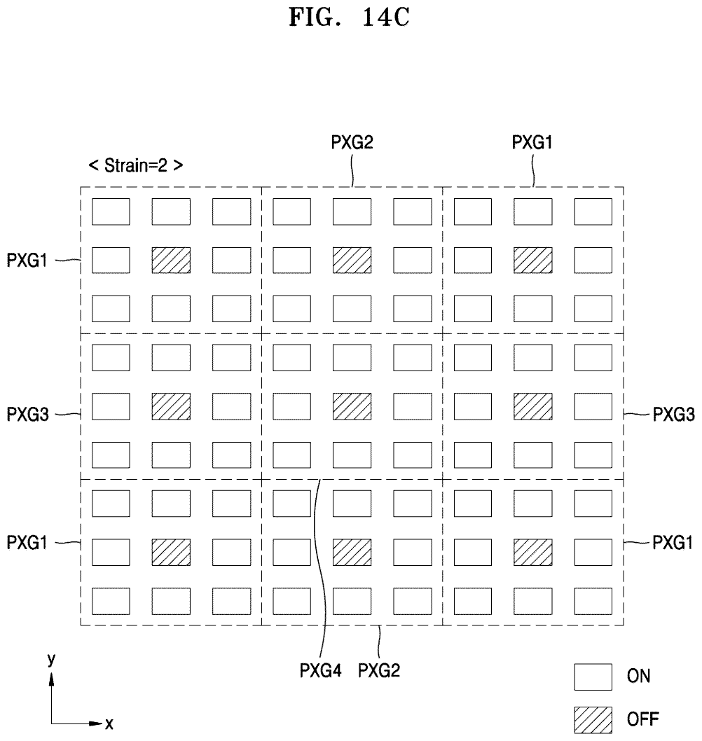

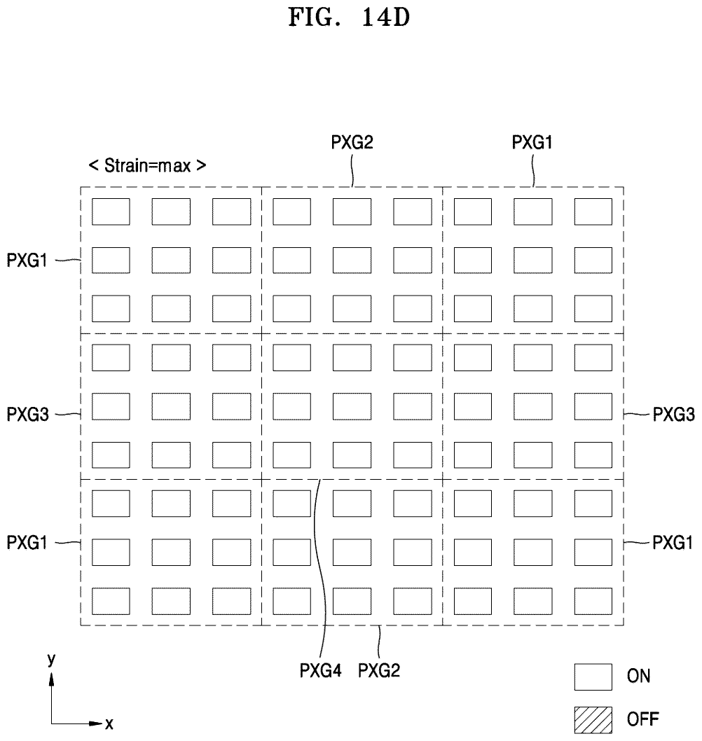

FIG. 13 is a diagram schematically illustrating the pixel group PXG according to one or more embodiments. FIGS. 14A to 14D are diagrams schematically illustrating a light emission state of the pixel group PXG according to the degree of stretching.

Referring to FIG. 13, the pixel group PXG may include nine pixels PX, that is, pixels PX11, PX12, PX13, PX21, PX22, PX23, PX31, PX32, and PX33, of 3×3.

In one or more embodiments, the pixel group PXG may include a first sub-pixel group SPXG1 and a second sub-pixel group SPXG2. The first sub-pixel group SPXG1 may include the pixels PX21, PX22, and PX23 that overlap a virtual line VL1 along a central row (an even row), among the nine pixels PX. The second sub-pixel group SPXG2 may include the pixels PX11, PX12, PX13, PX31, PX32, and PX33 that overlap virtual lines VL2 and VL3 along upper and lower rows (odd rows), among the nine pixels PX.

In a non-stretched state (e.g., Strain=0, and/or a first display mode), the first sub-pixel group SPXG1 or the second sub-pixel group SPXG2 in each pixel group PXG may emit light. For example, as shown in FIG. 14A, the first sub-pixel group SPXG1 in each pixel group PXG may emit light, and the second sub-pixel group SPXG2 in each pixel group PXG may not emit light. In the first display mode, among the nine pixels PX in each pixel group PXG, three pixels PX of the first sub-pixel group SPXG1 may emit light.

In a state in which the degree of stretching is 1 (e.g., Strain=1, and/or a second display mode), the number of pixels PX that emit light in each pixel group PXG may be greater than the number of pixels PX that emit light in each pixel group PXG in the first display mode. In one or more embodiments, at least one of the pixels PX that do not emit light in the first display mode may emit light, and at least one of the pixels PX that emit light in the first display mode may not emit light. For example, in each pixel group PXG, at least one of the pixels PX of the first sub-pixel group SPXG1 that emit light may not emit light, and/or at least one of the pixels PX of the second sub-pixel group SPXG2 that do not emit light may emit light.

As shown in FIG. 14B, in the second display mode, for every four pixel groups PXG, seven pixels PX (e.g., the pixels PX11, PX13, PX21, PX22, PX23, PX31, and PX33, as shown in FIG. 13) among nine pixels PX may emit light in a first pixel group PXG1, five pixels PX (e.g., the pixels PX12, PX21, PX22, PX23, and PX32, as shown in FIG. 13) among nine pixels PX may emit light in a second pixel group PXG2, eight pixels PX (e.g., the pixels PX11, PX12, PX13, PX21, PX23, PX31, PX32, and PX33, as shown in FIG. 13) among nine pixels PX may emit light in a third pixel group PXG3, and seven pixels PX (e.g., the pixels PX11, PX12, PX13, PX22, PX31, PX32, and PX33, as shown in FIG. 13) among nine pixels PX may emit light in a fourth pixel group PXG4.

In a state in which the degree of stretching is 2 (e.g., Strain=2, and/or a third display mode), the number of pixels PX that emit light in each pixel group PXG may be greater than the number of pixels PX that emit light in each pixel group PXG in the second display mode. In one or more embodiments, at least one of the pixels PX that do not emit light in the second display mode may emit light, and at least one of the pixels PX that emit light in the second display mode may not emit light. In each pixel group PXG, at least one of the pixels PX of the first sub-pixel group SPXG1 or the second sub-pixel group SPXG2 that emit light may not emit light, and/or at least one of the pixels PX of the first sub-pixel group SPXG1 or the second sub-pixel group SPXG2 that do not emit light may emit light. For example, as shown in FIG. 14C, in the third display mode, the pixel PX located at the center in each pixel group PXG may not emit light, and the remaining pixels PX may emit light. In the third display mode, eight pixels PX (e.g., the pixels PX11, PX12, PX13, PX21, PX23, PX31, PX32, and PX33, as shown in FIG. 13) among the nine pixels PX in each pixel group PXG may emit light.

In a state in which the degree of stretching is maximum (e.g., Strain=max, and/or a fourth display mode), the number of pixels PX that emit light in each pixel group PXG may be greater than the number of pixels PX that emit light in each pixel group PXG in the third display mode. For example, as shown in FIG. 14D, in the fourth display mode, all pixels PX in each pixel group PXG may emit light.

FIG. 12A and FIG. 14A show examples in which the pixels PX in the first sub-pixel group SPXG1 of each pixel group PXG emit light in the non-stretched state, but embodiments are not limited thereto. For example, in the non-stretched state, the pixels PX in the second sub-pixel group SPXG2 of each pixel group PXG may emit light. Alternatively, in the non-stretched state, the pixel group PXG in which the pixels PX in the first sub-pixel group SPXG1 emit light, and the pixel group PXG in which the pixels PX in the second sub-pixel group SPXG2 emit light, may alternate in the first direction and the second direction.

As shown in FIGS. 10A to 10D, 12A to 12D, and 14A to 14D, in the display device 1 of the disclosure, at each stretching stage corresponding to the degree of stretching of the display device 1, upper and lower pixels, left and right pixels, and/or diagonal pixels in each pixel group PXG may symmetrically emit light, or may symmetrically not emit light, with respect to a central pixel (e.g., the pixel PX22). In addition, when the display device 1 is in the stretched state, non-light-emitting pixels may not be located adjacent to each other in the first direction and the second direction. Accordingly, the visibility of the non-light-emitting pixels may be reduced at low resolutions.

In addition, in the display device 1 of the disclosure, as the degree of stretching of the display device 1 increases, the number of pixels that emit light in a pixel group increases to compensate for the resolution, thereby reducing resolution degradation due to stretching.

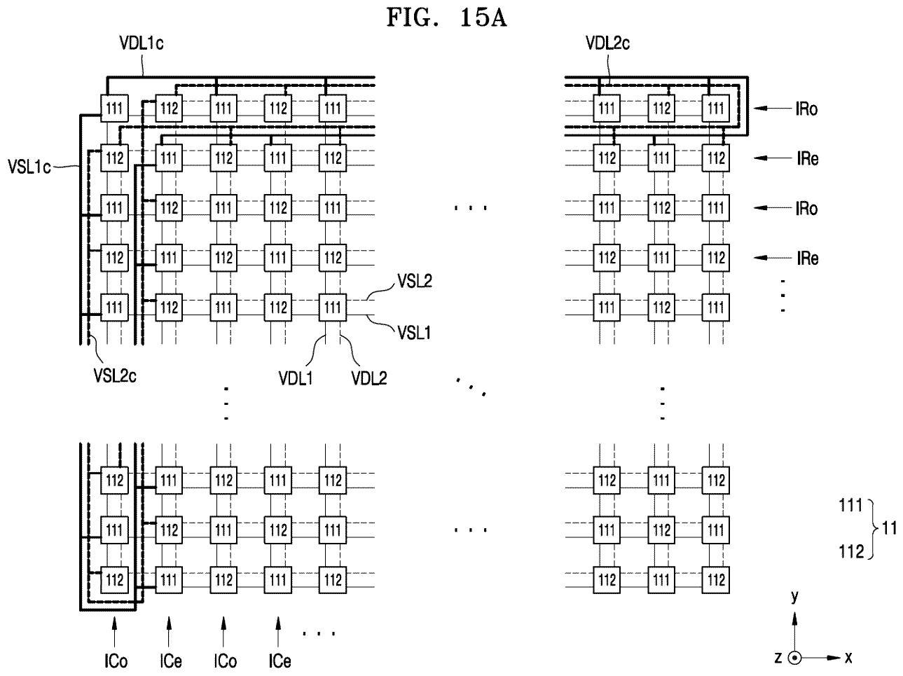

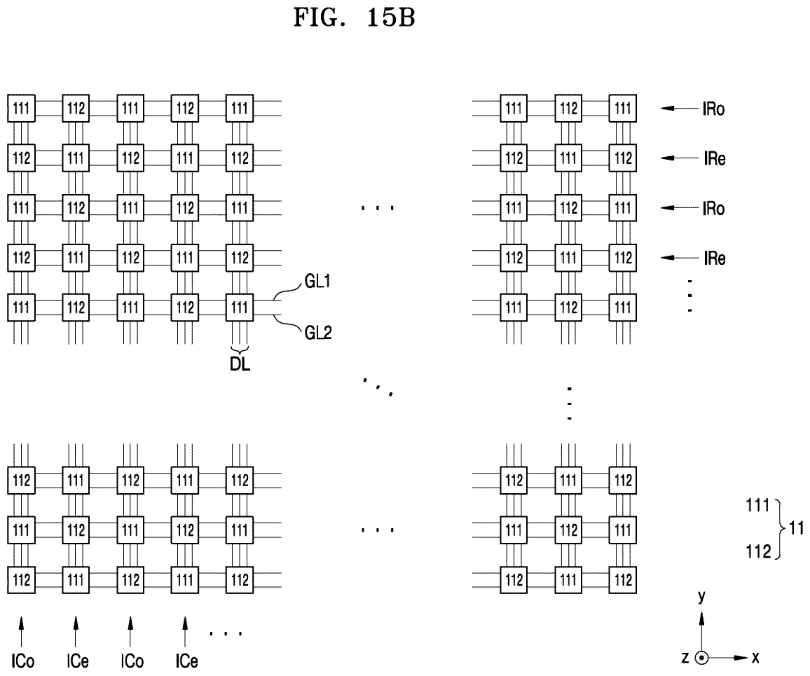

FIGS. 15A and 15B are diagrams schematically illustrating conductive lines in the display area DA according to one or more embodiments. FIG. 15A is a diagram schematically illustrating voltage lines in the display area DA, and FIG. 15B is a diagram schematically illustrating signal lines in the display area DA. The voltage lines may include a driving voltage line VDL and a common voltage line VSL. The signal lines may include a gate line GL and a data line DL.

Referring to FIGS. 15A and 15B, the first island portion 11 of the display area DA may include an eleventh island portion 111 and a twelfth island portion 112, which may respectively correspond to first island portions and second island portions in the claims.

A plurality of eleventh island portions 111 may be separated from each other in the first direction (e.g., the x-direction and/or the −x-direction) and the second direction (e.g., the y-direction and/or the −y-direction). A plurality of twelfth island portions 112 may be separated from each other in the first direction (e.g., the x-direction and/or the −x-direction) and the second direction (e.g., the y-direction and/or the −y-direction), so as to cross the plurality of eleventh island portions 111. The plurality of eleventh island portions 111 and the plurality of twelfth island portions 112 may be alternately separated from each other in the first direction (e.g., the x-direction and/or the −x-direction) and the second direction (e.g., the y-direction and/or the −y-direction). The eleventh island portion 111 and the twelfth island portion 112 may be alternately arranged in the first direction (e.g., the x-direction and/or the −x-direction). The eleventh island portion 111 and the twelfth island portion 112 may be alternately arranged in the second direction (e.g., the y-direction and/or the −y-direction).

The plurality of eleventh island portions 111 and the plurality of twelfth island portions 112 may be arranged in a grid shape. The plurality of eleventh island portions 111 and the plurality of twelfth island portions 112 may be arranged to form a plurality of rows and a plurality of columns. Here, a row may be an island portion row in which the first island portion 11 is arranged in the first direction, and a column may be an island portion column in which the first island portion 11 is arranged in the second direction. A row may correspond to a pixel row, and a column may correspond to a pixel column. A column or pixel column may include a plurality of sub-columns. The number of sub-columns included in a pixel column may be the number of sub-pixels constituting a pixel.

The plurality of eleventh island portions 111 may include the eleventh island portions 111 arranged in an area in which an odd row IRo and an odd column ICo cross each other, and may include the eleventh island portions 111 arranged at a location at which an even row IRe and an even column ICe cross each other. For example, the plurality of eleventh island portions 111 may be arranged at locations, such as (first row, first column), (first row, third column), (third row, first column), (third row, third column), (second row, second column), (second row, fourth column), (fourth row, second column), and (fourth row, fourth column).

The plurality of twelfth island portions 112 may include the twelfth island portions 112 arranged in an area in which the odd row IRo and the even column ICe cross each other, and may include the twelfth island portions 112 arranged at a location at which the even row IRe and the odd column ICo cross each other. For example, the plurality of twelfth island portions 112 may be arranged at locations, such as (first row, second column), (first row, fourth column), (third row, second column), (third row, fourth column), (second row, first column), (second row, third column), (fourth row, first column), and (fourth row, third column).

As shown in FIG. 15A, the driving voltage line VDL may include a first driving voltage line VDL1 and a second driving voltage line VDL2, and the common voltage line VSL may include a first common voltage line VSL1 and a second common voltage line VSL2.

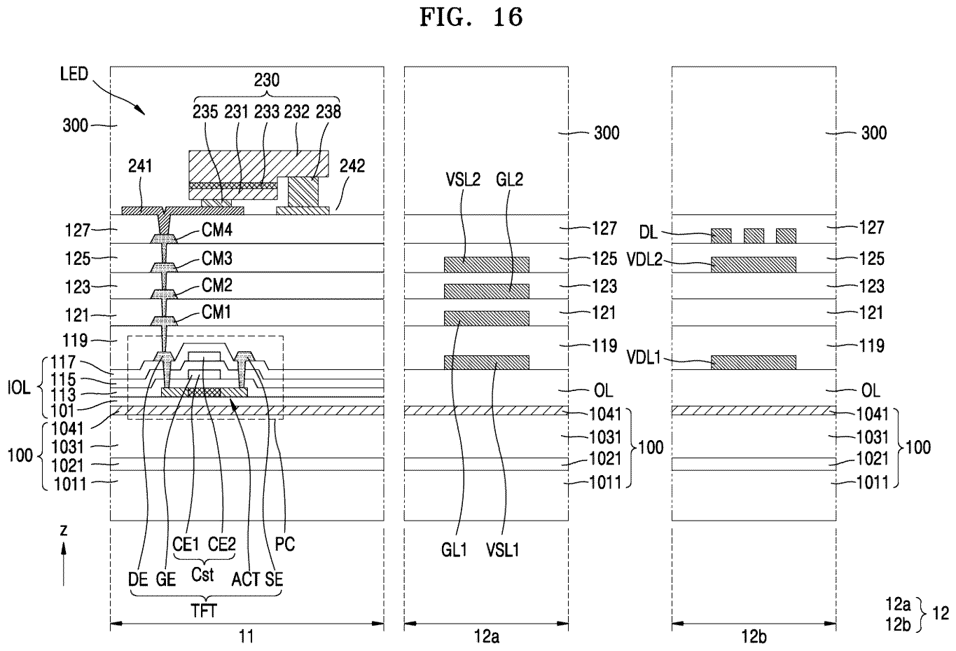

In each row in a plan view, the first common voltage line VSL1 and the second common voltage line VSL2 may extend in the first direction (e.g., the x-direction and/or the −x-direction), and may be arranged in a first bridge portion 12a (see FIG. 16) in the first direction. The first common voltage line VSL1 and the second common voltage line VSL2 of each row may overlap the plurality of eleventh island portions 111 and the plurality of twelfth island portions 112 of the corresponding row. The first common voltage line VSL1 of each row may be connected to the pixels PX arranged in the plurality of eleventh island portions 111 of the corresponding row. The second common voltage line VSL2 of each row may be connected to the pixels PX arranged in the plurality of twelfth island portions 112 of the corresponding row.

The first common voltage line VSL1 and the second common voltage line VSL2 of each row may be connected to the common voltage supply line 13 of the non-display area NDA. In one or more embodiments, the first common voltage lines VSL1 may be connected to the common voltage supply line 13 through a first common voltage connection line VSL1c, and the second common voltage lines VSL2 may be connected to the common voltage supply line 13 through a second common voltage connection line VSL2c.

The first common voltage connection line VSL1c may be connected to the pixels PX arranged in the plurality of eleventh island portions 111 located in odd rows of the first column and in the plurality of eleventh island portions 111 located in even rows of the second column. The second common voltage connection line VSL2c may be connected to the pixels PX arranged in the plurality of twelfth island portions 112 located in even rows of the first column and in the plurality of twelfth island portions 112 located in odd rows of the second column.

The first common voltage connection line VSL1c and the second common voltage connection line VSL2c may be connected to the common voltage supply line 13 of the non-display area NDA, may receive a common voltage from the common voltage supply line 13, and may transmit the common voltage to the first common voltage line VSL1 and the second common voltage line VSL2, respectively. In one or more embodiments, the common voltage may be a voltage that is input to an opposite electrode of a light-emitting element.

In each column in a plan view, the first driving voltage line VDL1 and the second driving voltage line VDL2 may extend in the second direction (e.g., the y-direction and/or the −y-direction), and may be arranged in a first bridge portion 12b (see FIG. 16) in the second direction. The first driving voltage line VDL1 and the second driving voltage line VDL2 of each column may overlap the plurality of eleventh island portions 111 and the plurality of twelfth island portions 112 of the corresponding column. The first driving voltage line VDL1 of each column may be connected to the pixels PX arranged in the plurality of eleventh island portions 111 of the corresponding column. The second driving voltage line VDL2 of each column may be connected to the pixels PX arranged in the plurality of twelfth island portions 112 of the corresponding column.

The first driving voltage line VDL1 and the second driving voltage line VDL2 of each column may be connected to the driving voltage supply line 15 of the non-display area NDA. In one or more embodiments, the first driving voltage lines VDL1 may be connected to the driving voltage supply line 15 through a first driving voltage connection line VDL1c, and the second driving voltage lines VDL2 may be connected to the driving voltage supply line 15 through a second driving voltage connection line VDL2c.

The first driving voltage connection line VDL1c may be connected to the pixels PX arranged in the plurality of eleventh island portions 111 located in odd columns of the first row and in the plurality of eleventh island portions 111 located in even columns of the second row. The second driving voltage connection line VDL2c may be connected to the pixels PX arranged in the plurality of twelfth island portions 112 located in even columns of the first row and in the plurality of twelfth island portions 112 located in odd columns of the second row.

The first driving voltage connection line VDL1c and the second driving voltage connection line VDL2c may be connected to the driving voltage supply line 15 of the non-display area NDA, may receive a driving voltage from the driving voltage supply line 15, and may transmit the driving voltage to the first driving voltage line VDL1 and the second driving voltage line VDL2, respectively. In one or more embodiments, the driving voltage may be supplied to a pixel electrode of a light-emitting element or to one end of a driving transistor connected to the pixel electrode.

As shown in FIG. 15B, the gate line GL may include a first gate line GL1 and a second gate line GL2. In each row in a plan view, the first gate line GL1 and the second gate line GL2 may extend in the first direction (e.g., the x-direction and/or the −x-direction), and may be arranged in the first bridge portion 12a (see FIG. 16) in the first direction. The first gate line GL1 and the second gate line GL2 of each row may overlap the plurality of eleventh island portions 111 and the plurality of twelfth island portions 112 of the corresponding row. The first gate line GL1 of each row may be connected to the pixels PX arranged in the plurality of eleventh island portions 111 of the corresponding row. The second gate line GL2 of each row may be connected to the pixels PX arranged in the plurality of twelfth island portions 112 of the corresponding row.

In each column in a plan view, the data line DL may extend in the second direction (e.g., the y-direction and/or the −y-direction), and may be arranged in the first bridge portion 12b (see FIG. 16) in the second direction. The data line DL of each column may overlap the plurality of eleventh island portions 111 and the plurality of twelfth island portions 112 of the corresponding column. The data line DL of each column may be connected to the pixels PX arranged in the plurality of eleventh island portions 111 and the plurality of twelfth island portions 112 of the corresponding column.

The number of data lines DL in each column may be the number of sub-pixels included in the pixel PX arranged in each of the eleventh island portion 111 and the twelfth island portion 112. For example, when the pixel PX arranged in each of the eleventh island portion 111 and the twelfth island portion 112 is the pixel PX shown in FIG. 7A, three data lines DL (a data line connected to a red pixel SPr, a data line connected to a green pixel SPg, and a data line connected to a blue pixel SPb) may be arranged in each column. For example, when the pixel PX arranged in each of the eleventh island portion 111 and the twelfth island portion 112 is the pixel PX shown in FIG. 7B, four data lines DL (a data line connected to a red pixel SPr, two data lines connected to two green pixels SPg, and a data line connected to a blue pixel SPb) may be arranged in each column. FIG. 15B shows an example in which three data lines DL are arranged in each column.

As shown in FIGS. 15A and 15B, because the driving voltage line VDL, the common voltage line VSL, and the gate line GL are each connected to non-adjacent ones of the pixels PX, the length of a conductive line connecting two pixels PX to each other may increase by more than two times, and thus, the stretching performance of the conductive line may increase, and strain stress due to stretching of the conductive line may be reduced. In addition, as a current flowing through one conductive line is distributed to two conductive lines, heat generation and power consumption by the conductive lines may be reduced.

FIG. 16 is a diagram schematically illustrating cross-sections of the first island portion 11, the first bridge portion 12a in the first direction, and the first bridge portion 12b in the second direction, according to one or more embodiments.

Referring to FIG. 16, the substrate 100 corresponding to the first island portion 11 may include a first base layer 1011, a first barrier layer 1021, a second base layer 1031, and a second barrier layer 1041. Materials of the first base layer 1011 and the second base layer 1031 are the same as those described with reference to FIG. 5. The first barrier layer 1021 and the second barrier layer 1041 may each include an inorganic insulating material, such as silicon oxide, silicon nitride, or silicon oxynitride.

A buffer layer 101 may be arranged on the substrate 100, and the pixel circuit PC may be arranged on the buffer layer 101 (as used herein, “arranged on” may mean “above”). The buffer layer 101 may include an inorganic insulating material, such as silicon oxide, silicon nitride, or silicon oxynitride. In one or more embodiments, the buffer layer 101 may be omitted.

The pixel circuit PC may include a thin-film transistor TFT, and the thin-film transistor TFT may include a semiconductor layer ACT, a gate electrode GE, a source electrode SE, and a drain electrode DE. FIG. 16 shows that the thin-film transistor TFT is of a top-gate type in which the gate electrode GE is arranged on the semiconductor layer ACT with a gate-insulating layer 113. The gate-insulating layer 113 may be between the semiconductor layer ACT and the gate electrode GE. However, in one or more other embodiments, the thin-film transistor TFT may be of a bottom gate type.

The semiconductor layer ACT may include polysilicon. Alternatively, the semiconductor layer ACT may include amorphous silicon, an oxide semiconductor, an organic semiconductor, etc. The gate electrode GE may include a low-resistance metal material. The gate electrode GE may include a conductive material including molybdenum (Mo), Al, copper (Cu), titanium (Ti), etc., and may include a single layer or multi-layer including the above-described material.

The gate-insulating layer 113 between the semiconductor layer ACT and the gate electrode GE may include an inorganic insulating material, such as silicon oxide, nitrogen oxide, silicon oxynitride, aluminum oxide, or titanium oxide. The gate-insulating layer 113 may include a single layer or multi-layer including the above-described material.

The source electrode SE and the drain electrode DE may be arranged on the same layer, for example, a second interlayer insulating layer 117, and may include the same material. The source electrode SE and the drain electrode DE may include a conductive material, and may include a multi-layer or single layer. The second interlayer insulating layer 117 may include an inorganic insulating material, such as silicon oxide, nitrogen oxide, silicon oxynitride, aluminum oxide, or titanium oxide, and may include a single layer or multi-layer including the above-described material.

A capacitor Cst may include a first electrode CE1 and a second electrode CE2 that overlap each other with a first interlayer insulating layer 115. The first interlayer insulating layer 115 may be between the first electrode CE1 and the second electrode CE2. The capacitor Cst may overlap the thin-film transistor TFT. FIG. 16 shows that the gate electrode GE of the thin-film transistor TFT is the first electrode CE1 of the capacitor Cst. In one or more other embodiments, the capacitor Cst may not overlap the thin-film transistor TFT. The capacitor Cst may be covered by the second interlayer insulating layer 117. The second electrode CE2 of the capacitor Cst may include a conductive material, and may include a multi-layer or single layer. The first interlayer insulating layer 115 may be arranged between the gate-insulating layer 113 and the second interlayer insulating layer 117. The first interlayer insulating layer 115 may include an inorganic insulating material, such as silicon oxide, nitrogen oxide, silicon oxynitride, aluminum oxide, or titanium oxide, and may include a single layer or multi-layer including the above-described material.

An inorganic insulating material layer IOL on the substrate 100 may include, for example, the buffer layer 101, the gate-insulating layer 113, the first interlayer insulating layer 115, and the second interlayer insulating layer 117.

A first organic insulating layer 119 may be arranged on the second interlayer insulating layer 117, a second organic insulating layer 121 may be arranged on the first organic insulating layer 119, a third organic insulating layer 123 may be arranged on the second organic insulating layer 121, a fourth organic insulating layer 125 may be arranged on the third organic insulating layer 123, and a fifth organic insulating layer 127 may be arranged on the fourth organic insulating layer 125. The first organic insulating layer 119, the second organic insulating layer 121, the third organic insulating layer 123, the fourth organic insulating layer 125, and the fifth organic insulating layer 127 may each include an organic insulating material, such as polyimide.

The light-emitting element LED may be arranged on the substrate 100. The light-emitting element LED may be arranged on the fifth organic insulating layer 127. FIG. 16 shows that the light-emitting element LED is the inorganic light-emitting diode 230 described with reference to FIG. 6B. However, in one or more other embodiments, the light-emitting element LED may be the organic light-emitting diode 220 described with reference to FIG. 6A. Hereinafter, descriptions are provided on the assumption that the light-emitting element LED is the inorganic light-emitting diode 230.

The first electrode pad 241 and the second electrode pad 242 may be arranged on the fifth organic insulating layer 127. The first electrode pad 241 may be connected to the thin-film transistor TFT through a first connection electrode CM1 between the first organic insulating layer 119 and the second organic insulating layer 121, a second connection electrode CM2 between the second organic insulating layer 121 and the third organic insulating layer 123, a third connection electrode CM3 between the third organic insulating layer 123 and the fourth organic insulating layer 125, and a fourth connection electrode CM4 between the fourth organic insulating layer 125 and the fifth organic insulating layer 127. The second electrode pad 242 may be connected to the common voltage line VSL. The inorganic light-emitting diode 230 on the first electrode pad 241 and the second electrode pad 242 is the same as described above with reference to FIG. 6B. The inorganic light-emitting diode 230 may be protected by the encapsulation layer 300, and the encapsulation layer 300 may include an inorganic encapsulation layer and/or an organic encapsulation layer, or may include an organic material, such as a resin.

In one or more embodiments, the substrate 100 corresponding to the first bridge portion 12 may have a stacked structure that is identical to that of the substrate 100 corresponding to the first island portion 11. In one or more embodiments, the substrate 100 corresponding to first bridge portion 12 may include the first base layer 1011, the first barrier layer 1021, the second base layer 1031, and the second barrier layer 1041. In one or more other embodiments, the substrate 100 corresponding to the first bridge portion 12 may have a stacked structure that is different from that of the substrate 100 corresponding to the first island portion 11. The substrate 100 corresponding to the first bridge portion 12 may have a structure including the first base layer 1011 and the second base layer 1031.

The inorganic insulating material layer IOL may not be arranged on the substrate 100, and an insulating layer OL, the first organic insulating layer 119, the second organic insulating layer 121, the third organic insulating layer 123, the fourth organic insulating layer 125, and the fifth organic insulating layer 127 may be arranged on the substrate 100. The encapsulation layer 300 may be arranged on the fifth organic insulating layer 127. The insulating layer OL may be an organic insulating layer including an organic insulating material, such as polyimide. In one or more embodiments, the insulating layer OL may have a thickness corresponding to the inorganic insulating material layer IOL. In some embodiments, the insulating layer OL may be omitted.

The first common voltage line VSL1 and the second common voltage line VSL2 may be arranged on different layers in the first bridge portion 12a in the first direction, and portions of the first common voltage line VSL1 and the second common voltage line VSL2 may overlap each other in a plan view. In one or more embodiments, one of the first common voltage line VSL1 or the second common voltage line VSL2 may be arranged on the insulating layer OL, and the other one of the first common voltage line VSL1 or the second common voltage line VSL2 may be arranged on the third organic insulating layer 123. FIG. 16 shows an example in which the first common voltage line VSL1 is arranged on the insulating layer OL, and the second common voltage line VSL2 is arranged on the third organic insulating layer 123.

The first gate line GL1 and the second gate line GL2 may be arranged on different layers in the first bridge portion 12a in the first direction, and portions of the first gate line GL1 and the second gate line GL2 may overlap each other in a plan view. In one or more embodiments, the first gate line GL1 and the second gate line GL2 may be arranged between the first common voltage line VSL1 and the second common voltage line VSL2. One of the first gate line GL1 and the second gate line GL2 may be arranged on the first organic insulating layer 119, and the other of the first gate line GL1 and the second gate line GL2 may be arranged on the second organic insulating layer 121. FIG. 16 shows an example in which the first gate line GL1 is arranged on the first organic insulating layer 119, and the second gate line GL2 is arranged on the second organic insulating layer 121.

The first driving voltage line VDL1 and the second driving voltage line VDL2 may be arranged on different layers in the first bridge portion 12b in the second direction, and portions of the first driving voltage line VDL1 and the second driving voltage line VDL2 may overlap each other in a plan view. In one or more embodiments, one of the first driving voltage line VDL1 or the second driving voltage line VDL2 may be arranged on the insulating layer OL, and the other one of the first driving voltage line VDL1 or the second driving voltage line VDL2 may be arranged on the third organic insulating layer 123. FIG. 16 shows an example in which the first driving voltage line VDL1 is arranged on the insulating layer OL, and the second driving voltage line VDL2 is arranged on the third organic insulating layer 123.

The data line DL may be arranged on the first bridge portion 12b in the second direction. In one or more embodiments, the data line DL may be arranged on the fourth organic insulating layer 125, and the fifth organic insulating layer 127 may be arranged on the data line DL.

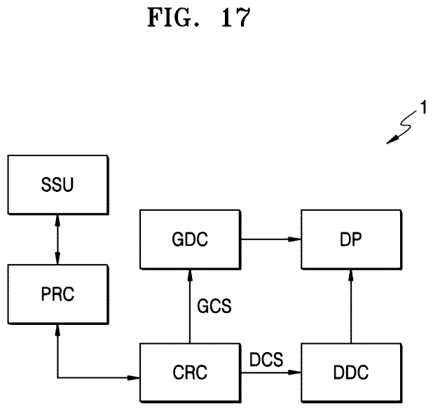

FIG. 17 is a diagram schematically illustrating an electronic device including the display device 1, according to one or more embodiments.

The resolution of the display device 1 may be determined by a distance between the pixels PX in the pixel group PXG, and as the distance between the pixels PX decreases, the resolution may increase. The display device 1 may provide a function of changing the resolution by controlling the number of pixels PX that emit light in the pixel group PXG, according to the degree of stretching. As the degree of stretching increases, the distance between the pixels PX may increase, but as the degree of stretching increases, the number of pixels PX that emit light in the pixel group PXG may increase, thereby compensating for the resolution.

Referring to FIG. 17, the electronic device according to one or more embodiments may include the display device 1 and a processor PRC. The display device 1 may include a display panel DP, a gate driver GDC, a data driver DDC, a controller CRC, and a sensing unit SSU.

A plurality of pixels PX may be arranged in a display area DA of the display panel DP. The pixel PX may include a plurality of sub-pixels that emit light of different colors.

A plurality of gate lines, a plurality of data lines, a plurality of driving voltage lines, and a plurality of common voltage lines may be arranged in the display area DA of the display panel DP. Each sub-pixel may be connected to at least one corresponding gate line among the plurality of gate lines GL and a corresponding data line among the plurality of data lines DL.

The gate lines may each extend in the first direction, and may be connected to the pixels PX located in the same row. The gate lines may each be configured to transmit a gate signal to the pixels PX in the same row. The data lines may each extend in the second direction, and may be connected to sub-pixels located in the same sub-column. The data lines may each be synchronized with a gate signal, and may be configured to transmit a data signal to each of the sub-pixels in the same sub-column.

The controller CRC may drive the pixels PX of the display panel DP under control by the processor PRC. The plurality of pixels PX may display an image signal received from the controller CRC.

The gate driver GDC may be connected to a plurality of gate lines, may generate gate signals in response to a control signal GCS from the controller CRC, and may sequentially supply the gate signals to the gate lines.

The data driver DDC may be connected to a plurality of data lines, and may supply data signals to the data lines in response to a control signal DCS from the controller CRC. The data signal supplied through the data line may be supplied to a sub-pixel to which a gate signal is supplied. The data driver DDC may convert image data or corrected image data having gray levels, which is input from the controller CRC, into a data signal in the form of a voltage or current. The data driver DDC may be integrated into another component (e.g., the controller CRC).

The controller CRC may receive an image signal from the processor PRC, may convert the data format of the image signal to match the interface specifications of the display device 1, and may output the image data to the data driver DDC. The controller CRC may be a timing controller. The controller CRC may generate control signals GCS and DCS based on signals input from the processor PRC, and may supply the control signals GCS and DCS to the gate driver GDC and the data driver DDC, respectively. The control signal GCS output to the gate driver GDC may include a plurality of clock signals and a gate start signal. The control signal DCS output to the data driver DDC may include a plurality of clock signals and a data start signal.

The sensing unit SSU may sense stretching of the display device 1, and may generate a sensing signal. The sensing unit SSU may include a strain sensor (a stretching sensor). In one or more embodiments, the strain sensor may measure capacitance or resistance, and may transmit, to the processor PRC, a capacitance change (amount) or resistance change (amount) as a sensing signal (sensing data). The disclosure is not limited to the above-described stretching sensing method, and the sensing unit SSU may sense stretching of the display device 1 in various ways. For example, the sensing unit SSU may sense stretching of the display device 1 by using various sensors, such as an acceleration sensor, an angular velocity sensor, a gyro sensor, and a current sensor. The sensing unit SSU may sense stretching of the display device 1 in each of x-axis, y-axis, and z-axis directions. In one or more embodiments, the sensing unit SSU may be a built-in device provided in the display panel DP or an external device provided outside the display panel DP.

The processor PRC may control an overall operation of the display device 1. In one or more embodiments, the processor PRC may be a microprocessor, an application processor (AP), etc. The processor PRC may receive data or instructions from a user, and may control the controller CRC based on the input data or instructions. The processor PRC may be implemented as a graphics card, a system-on-chip (SOC), etc. The processor PRC may provide image data to the controller CRC.

The processor PRC may determine the degree of stretching of the display device 1 based on a sensing signal obtained from the sensing unit SSU. The processor PRC may derive stretching information of the display device 1 from the sensing signal, and may determine the degree of stretching based on the stretching information. The processor PRC may determine a display mode according to the degree of stretching, and may control light emission of pixels for each pixel group PXG according to the display mode. The processor PRC may provide, to the controller CRC, an image signal for displaying an image in a display mode corresponding to the degree of stretching.

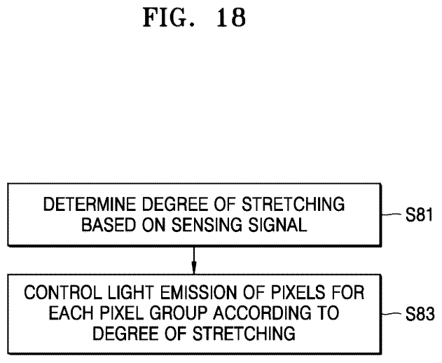

FIG. 18 is a diagram schematically explaining driving of the display device 1 according to one or more embodiments.

The diagram shown in FIG. 18 includes operations that are processed in time series in an electronic device including the display device 1 described above, particularly in the processor PRC. Accordingly, while some descriptions are omitted below, the descriptions provided above may also apply to the flowchart shown in FIG. 18.

Referring to FIG. 18, the processor PRC may receive a sensing signal from the sensing unit SSU, may calculate stretching information of the display device 1 from the sensing signal, and may determine the degree of stretching based on the stretching information (S81).

The processor PRC may determine a display mode of the display device 1 according to the degree of stretching, and may control light emission of pixels in units of pixel groups PXG to correspond to the display mode (S83). The processor PRC may provide, to the controller CRC, an image signal corresponding to the display mode.

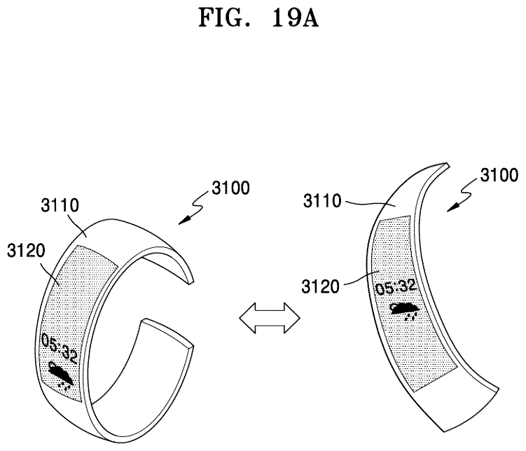

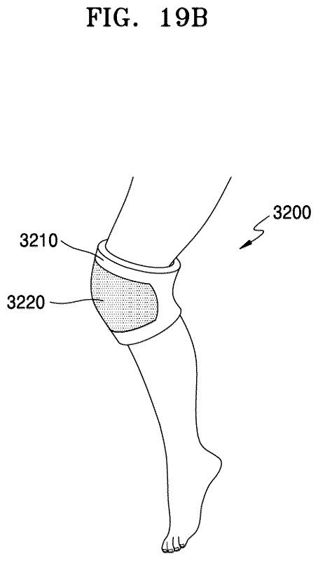

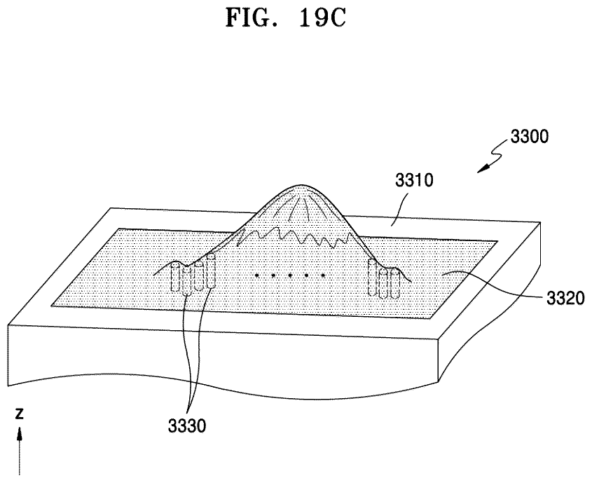

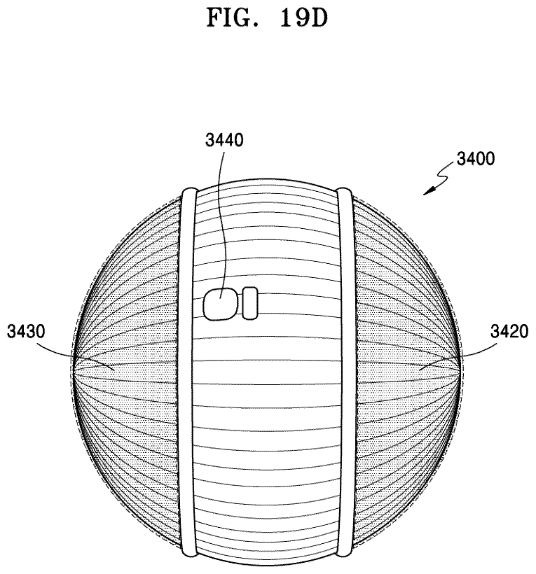

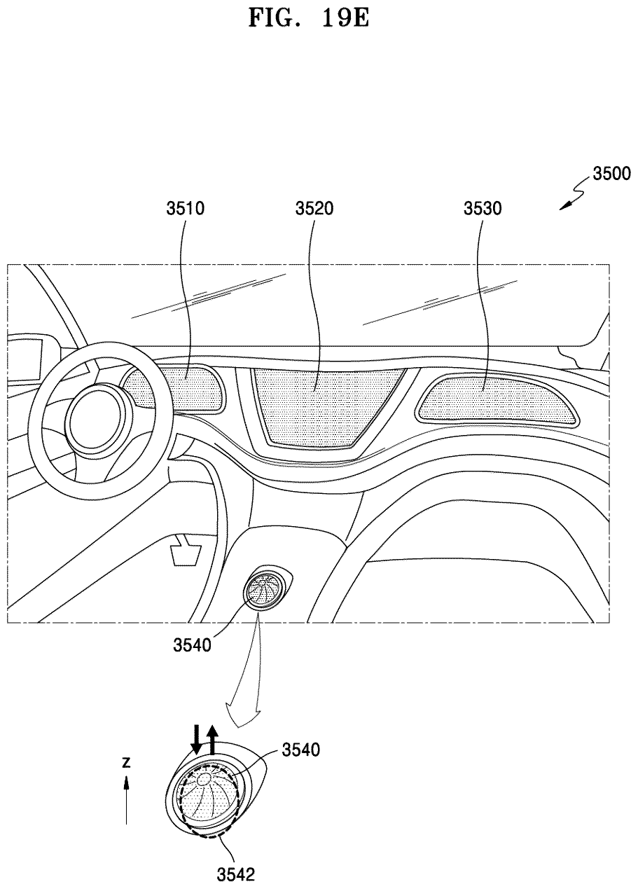

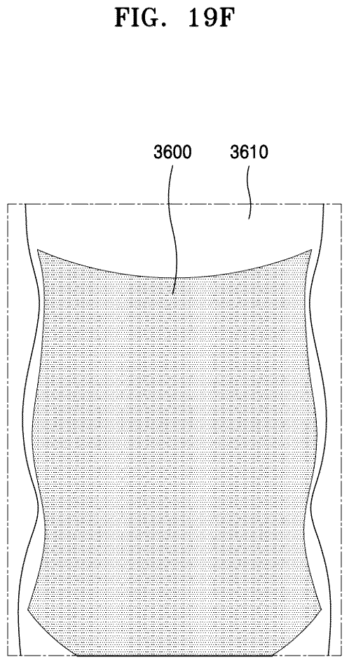

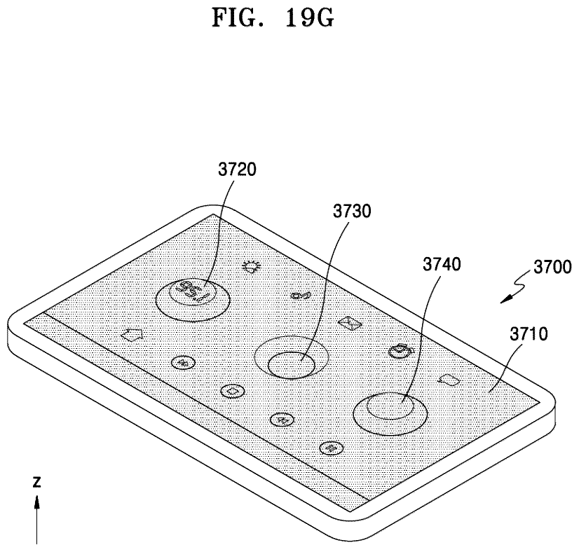

FIGS. 19A to 19G are perspective views schematically illustrating embodiments of electronic devices each including a display device according to one or more embodiments.

Referring to FIG. 19A, a display device according to one or more embodiments may be used in a wearable electronic device 3100 that may be worn on a part of a user's body. The wearable electronic device 3100 may include a body portion 3110 and a display 3120 provided on the body portion 3110. A stretchable display device according to embodiments may be used as the display 3120 of the wearable electronic device 3100. As shown in FIG. 19A, the wearable electronic device 3100 may be deformable. In one or more embodiments, the wearable electronic device 3100 may be used as a smart watch or a smartphone according to the user's choice.

FIG. 19B shows a medical electronic device 3200. In one or more embodiments, the medical electronic device 3200 may include a body portion 3210 and an emission portion 3220. A stretchable display device according to embodiments may be used as the emission portion 3220 of the medical electronic device 3200. The emission portion 3220 may emit light of a corresponding wavelength band (e.g., infrared light, visible light, etc.) to a patient's body. In one or more embodiments, the body portion 3210 may include a stretchable fiber material, and may have a structure that may be worn on the body of a user of the emission portion 3220.

FIG. 19C shows an educational electronic device 3300. In one or more embodiments, the educational electronic device 3300 may include a display 3320 provided within a frame 3310. The display 3320 may use a display device according to embodiments. The display 3320 may provide an image of a sea with waves, a mountain covered in snow, or a volcano with flowing lava, and in this case, the display 3320 may be stretched in a height direction (e.g., the z-direction) to reflect the height of the waves, the mountain, or the volcano. In some embodiments, the height of a portion of the display 3320 may sequentially vary in a direction in which the lava flows, thereby displaying movement of the lava in three dimensions. The educational electronic device 3300 may include a plurality of pins (or stroke portions) 3330 arranged on a rear surface of the display 3320 so that the display 3320 is stretched in the height direction. As the pins 3330 move in the third direction (e.g., the z-direction or the −z-direction), an image expressed on the display 3320 may be implemented to have a three-dimensional height. While FIG. 19C illustrates the educational electronic device 3300, the use of the illustrated electronic device is not limited as long as it provides image information.

The electronic devices shown in FIGS. 19A to 19C may each have a variable shape, but the disclosure is not limited thereto. As in embodiments to be described below, a stretchable display device according to embodiments may be used in an electronic device in which a portion capable of expressing an image (e.g., a screen) is fixed.

FIG. 19D shows a robot 3400 as an electronic device according to one or more embodiments. The robot 3400 may recognize movement or an object by using a camera 3440, and may display an image to a user through displays 3420 and 3430. In some embodiments, because stretchable display devices according to one or more embodiments may be stretched in various directions, as described above, the stretchable display devices may be assembled into a body frame having a hemispherical shape, and thus, the robot 3400 may include the displays 3420 and 3430 each having a hemispherical shape.

FIG. 19E shows a vehicle display device 3500 as an electronic device according to one or more embodiments. The vehicle display device 3500 may include a cluster 3510, a center information display (CID) 3520, and/or a passenger display 3530. Because a stretchable display device according to one or more embodiments may be stretched in various directions, the stretchable display device may be used in the cluster 3510, the CID 3520, and/or the passenger display 3530 regardless of the shape of an internal frame of a vehicle.

FIG. 19E shows that the cluster 3510, the CID 3520, and/or the passenger display 3530 are separated from each other, but the disclosure is not limited thereto. In one or more other embodiments, two or more selected from the cluster 3510, the CID 3520, and/or the passenger display 3530 may be connected into a single body.

In some embodiments, the vehicle display device 3500 may include a button 3540 capable of expressing an image. Referring to the enlarged view of FIG. 19E, the button 3540 having a hemispherical shape may include an object 3542 for providing a feeling of use of the button 3540 while moving in the z-direction or the −z-direction, and a stretchable display device arranged on the object 3542. In some embodiments, when the object 3542 has a three-dimensionally round surface, the stretchable display device may also have a three-dimensionally round surface.

FIG. 19F shows an electronic device 3600 for advertising or exhibition as an electronic device according to one or more embodiments. In some embodiments, the electronic device 3600 for advertising or exhibition may be installed on a structure 3610 that is fixed, such as a wall or a pillar. When the structure 3610 includes an uneven surface as shown in FIG. 19F, the electronic device 3600 for advertising or exhibition may be arranged along the uneven surface of the structure 3610. In some embodiments, the electronic device 3600 for advertising or exhibition may be installed on the structure 3610 by using a heat-shrink film, etc.

FIG. 19G shows a controller 3700 as an electronic device according to one or more embodiments. The controller 3700 may include an image-type button. For example, the controller 3700 may include first to third button areas 3720, 3730, and 3740 in which portions of a display 3710 protrude in the z-direction or protrude in the −z-direction (or are recessed in the z-direction). In some embodiments, the first and third button areas 3720 and 3740 may protrude in the z-direction, and the second button area 3730 may protrude in the −z-direction (or be recessed in the z-direction).

According to the one or more embodiments, a display device having improved display quality may be provided. However, the scope of the disclosure is not limited thereto.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display device configured to be stretched, the display device comprising a display panel comprising pixels in pixel groups repeatedly arranged in a first direction and a second direction in a display area, wherein:
each of the pixel groups comprises a first sub-pixel group and a second sub-pixel group,
the pixels in the first sub-pixel group and the second sub-pixel group in each of the pixel groups are configured to emit light or not to emit light when the display device is in a stretched state such that a number of light-emitting pixels of the pixels increases as a degree of stretching of the display device increases, and
ones of the pixels in the first sub-pixel group or in the second sub-pixel group in each of the pixel groups are configured to emit light when the display device is in a non-stretched state.

2. The display device of claim 1, wherein locations of the light-emitting pixels are repeated in units of pixel groups when the display device is in the stretched state.

3. The display device of claim 1, wherein upper, lower, left, right, and/or diagonal ones of the pixels are configured to symmetrically emit light or to symmetrically not emit light, with respect to a central one of the pixels, and corresponding to the degree of the stretching.

4. The display device of claim 1, wherein non-light-emitting pixels of the pixels are not adjacent in the first direction or the second direction when the display device is in the stretched state.

5. The display device of claim 1, wherein the display area comprises island portions and bridge portions connecting the island portions, and
wherein the pixels are in the island portions and comprise sub-pixels, and
wherein the display panel further comprises conductive lines connected to the pixels in the bridge portions.

6. The display device of claim 5, wherein the island portions comprise first island portions and second island portions that are alternately arranged and separated in the first direction and the second direction.

7. The display device of claim 6, wherein the bridge portions comprise:
first bridge portions connecting island portions arranged in the first direction; and
second bridge portions connecting island portions arranged in the second direction.

8. The display device of claim 7, further comprising:
a first common voltage line and a second common voltage line in the first bridge portions, the first common voltage line being connected to ones of the pixels in the first island portions arranged in the first direction, and the second common voltage line being connected to others of the pixels in the second island portions arranged in the first direction; and
a first driving voltage line and a second driving voltage line in the second bridge portions, the first driving voltage line being connected to ones of the pixels in the first island portions arranged in the second direction, and the second driving voltage line being connected to others of the pixels in the second island portions arranged in the second direction.

9. The display device of claim 8, wherein the first common voltage line and the second common voltage line are at different respective layers, and
wherein the first driving voltage line and the second driving voltage line are at different respective layers.

10. The display device of claim 7, further comprising:
a first gate line and a second gate line in the first bridge portions, the first gate line being connected to ones of the pixels in the first island portions arranged in the first direction, and the second gate line being connected to others of the pixels in the second island portions arranged in the first direction, and
a data line in the second bridge portions and connected to ones of the pixels in the first island portions and in the second island portions arranged in the second direction.

11. The display device of claim 8, further comprising:
a common voltage supply line in a non-display area outside the display area and connected to the first common voltage line and the second common voltage line; and
a driving voltage supply line in the non-display area and connected to the first driving voltage line and the second driving voltage line.

12. A display device configured to be stretched, and having a display area, and a non-display area outside the display area, the display device comprising:
conductive lines; and
pixel groups connected to the conductive lines and arranged in a first direction and in a second direction in the display area, each of the pixel groups comprising pixels in a first sub-pixel group and in a second sub-pixel group, and wherein:
the pixels in the first sub-pixel group and in the second sub-pixel group in each of the pixel groups are configured to emit light or not to emit light such that a number of light-emitting pixels of the pixels increases as a degree of stretching of the display device increases, and
ones of the pixels in the first sub-pixel group or in the second sub-pixel group in each of the pixel groups are configured to emit light when the display device is in a non-stretched state.

13. The display device of claim 12, wherein the display area comprises:
first island portions and second island portions with the pixels therein, and alternately arranged to be separated in the first direction and the second direction in the display area; and
bridge portions with the conductive lines therein, and connecting the first island portions and the second island portions.

14. The display device of claim 13, wherein the conductive lines comprise:
a common voltage line comprising a first common voltage line connected to ones of the pixels in the first island portions arranged in the first direction, and a second common voltage line connected to others of the pixels in the second island portions arranged in the first direction; and
a driving voltage line comprises a first driving voltage line connected to ones of the pixels in the first island portions arranged in the second direction, and a second driving voltage line connected to others of the pixels in the second island portions arranged in the second direction.

15. The display device of claim 14, wherein the first common voltage line and the second common voltage line are at different respective layers, and
wherein the first driving voltage line and the second driving voltage line are at different respective layers.

16. The display device of claim 12, wherein, upper, lower, left, right, and/or diagonal ones of the pixels are configured to symmetrically emit light or to symmetrically not emit light with respect to a central pixel corresponding to the degree of the stretching.

17. The display device of claim 16, wherein non-light-emitting pixels of the pixels are not adjacent in the first direction or the second direction when the display device is in the stretched state.

18. An electronic device comprising:
a display device comprising pixels in pixel groups repeatedly arranged in a first direction and a second direction in a display area, each of the pixel groups comprising a first sub-pixel group and a second sub-pixel group;
a sensing unit configured to sense stretching of the display device; and
a processor configured to:
receive, from the sensing unit, a sensing signal corresponding to the stretching;
determine a degree of the stretching based on the sensing signal;
output an image signal corresponding to the degree of the stretching,
control ones of the pixels of the first sub-pixel group or of the second sub-pixel group to emit light when the display device is in a non-stretched state; and
control the pixels of the first sub-pixel group and of the second sub-pixel group to emit light or not to emit light when the display device is in a stretched state such that a number of light-emitting pixels of the pixels increases as the degree of the stretching increases.

19. The electronic device of claim 18, wherein upper, lower, left, right, and/or diagonal ones of the pixels are configured to symmetrically emit light or to symmetrically not emit light with respect to a central pixel corresponding to the degree of the stretching.

20. The electronic device of claim 18, wherein non-light-emitting pixels of the pixels are not adjacent in the first direction or the second direction when the display device is in the stretched state.
